(19) United States
(12) Patent Application Publication
(10) Pub. No.: US 2014/0151659 A1
(43) Pub. Date: Jun. 5, 2014

(54) LIGHT-EMITTING COMPOUND

(71) Applicants: Sumitomo Chemical Company Limited, Tokyo (JP); Cambridge Display Technology, Cambridgeshire (GB)

(72) Inventors: Kiran Kamtekar, Cambridgeshire (GB); Annette Steudel, Cambridgeshire (GB)

(73) Assignees: Sumitomo Chemical Company Limited, Tokyo (JP); Cambridge Display Technology, Cambridgeshire (GB)

(21) Appl. No.: 14/091,146

(22) Filed: Nov. 26, 2013

(30) Foreign Application Priority Data
Nov. 30, 2012 (GB) 1221621.4

(51) Int. Cl. H01L 51/00

(52) U.S. Cl. CPC H01L 51/0085; H01L 51/0002
USPC 257/40; 548/103; 252/519.2; 252/519.21; 438/46

(57) ABSTRACT

An unsubstituted or substituted phosphorescent compound of formula (I):

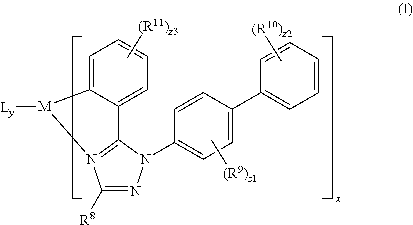

Wherein:
M is a transition metal;
L in each occurrence is independently a mono- or poly-dentate ligand;
R⁸ is H or a substituent;
R⁹ and R¹⁰ are each independently selected from the group consisting of branched, linear or cyclic C₁₋₂₀ alkyl wherein non-adjacent C atoms of the C₁₋₂₀ alkyl may be replaced with —O—, —S—, —NR¹²—, —SiR¹²₂— or —COO— and one or more H atoms may be replaced with F or —NR¹²₂, wherein R¹² is H or a substituent;
R¹¹ in each occurrence is independently H or a substituent, wherein two groups R¹¹ may be linked to form a ring;
x is at least 1;
y is 0 or a positive integer;
and z1, z2 and z3 are each independently 0 or a positive integer.

### FIELD OF THE INVENTION

The present invention relates to light-emitting compounds, in particular phosphorescent light-emitting compounds; compositions, solutions and light-emitting devices comprising said light-emitting compounds; and methods of making said light-emitting devices.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

Suitable light-emitting materials include small molecule, polymeric and dendrimeric materials. Suitable light-emitting polymers include poly(arylene vinylenes) such as poly(p-phenylene vinylenes) and polyarylenes such as polyfluorenes.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton).

Phosphorescent dopants are also known (that is, a light-emitting dopant in which light is emitted via decay of a triplet exciton).

WO 2004/101707 discloses blue phosphorescent metal complexes containing phenyltriazole ligands.

US 2007/088167 discloses metal complexes containing certain substituted phenylimidazole ligands.

US 2012/133273 discloses metal complexes containing certain aryltriazole ligands.

US 2006/251923 discloses metal complexes containing certain substituted phenylimidazole ligands.

It is an object of the invention to provide a blue phosphorescent light-emitting compound suitable for use in an OLED.

It is a further objection of the invention to provide a phosphorescent light-emitting compound having long operational life when used in an OLED.

### SUMMARY OF THE INVENTION

In a first aspect the invention provides an unsubstituted or substituted phosphorescent compound of formula (I):

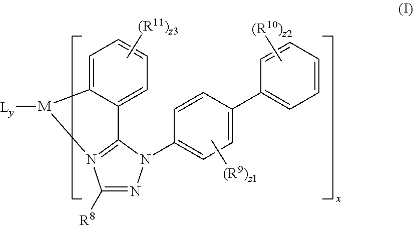

wherein:
M is a transition metal;
L in each occurrence is independently a mono- or poly-dentate ligand;
R⁸ is H or a substituent;
R⁹ and R¹⁰ are each independently selected from the group consisting of branched, linear or cyclic C₁₋₂₀ alkyl wherein non-adjacent C atoms of the C₁₋₂₀ alkyl may be replaced with —O—, —S—, —NR¹²—, —SiR¹²₂— or —COO— and one or more H atoms may be replaced with F or —NR¹²₂, wherein R¹² is H or a substituent;
R¹¹ in each occurrence is independently H or a substituent, wherein two groups R¹¹ may be linked to form a ring;
x is at least 1;
y is 0 or a positive integer;
and z1, z2 and z3 are each independently 0 or a positive integer.

In a second aspect the invention provides a composition comprising a host material and a compound according to the first aspect.

In a third aspect the invention provides a solution comprising a compound of the first aspect or composition of the second aspect dissolved in one or more solvents.

In a fourth aspect the invention provides an organic light-emitting device comprising an anode, a cathode and a light-emitting layer between the anode and cathode wherein the light-emitting layer comprises a compound or composition according to the first or second aspect.

In a fifth aspect the invention provides a method of forming an organic light-emitting device according to the fourth aspect, the method comprising the step of depositing the light-emitting layer over one of the anode and cathode, and depositing the other of the anode and cathode over the light-emitting layer.

### DESCRIPTION OF THE DRAWINGS

The invention will now be described in more detail with reference to the Figures, in which:

FIG. 1 illustrates an OLED according to an embodiment of the invention;

FIG. 2 illustrates energy levels of the OLED of FIG. 1;

FIG. 3 shows luminance decay curves for a blue light emitting device according to an embodiment of the invention and a comparative blue device;

FIG. 4 shows the electroluminescence spectra for the devices of FIG. 3;

FIG. 5 shows the electroluminescent spectra for a blue light emitting device according to an embodiment of the invention and a comparative blue device;

FIG. 6 shows the electroluminescent spectra for a blue light emitting device according to an embodiment of the invention and two comparative blue devices;

FIG. 7 shows the electroluminescent spectra for a white light emitting device according to an embodiment of the invention and a comparative white device; and

FIG. 8 shows the electroluminescent spectra for a white light emitting device according to an embodiment of the invention and a comparative white device.

### DETAILED DESCRIPTION OF THE INVENTION

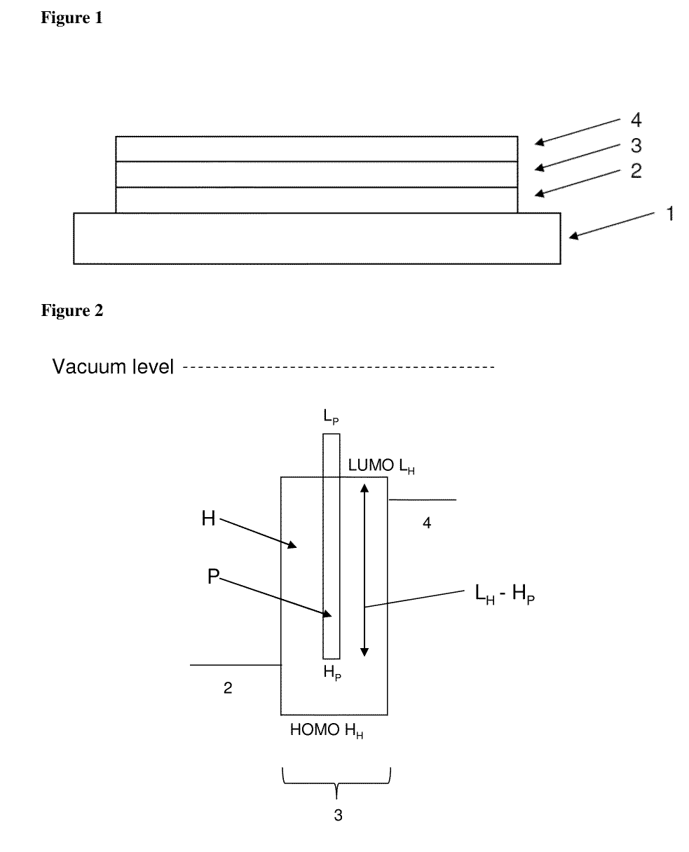

FIG. 1, which is not drawn to any scale, illustrates schematically an OLED 100 according to an embodiment of the invention. The OLED 100 is carried on substrate 107 and comprises an anode 101, a cathode 105 and a light-emitting layer 103 between the anode and the cathode. Further layers (not shown) may be provided between the anode and the cathode including, without limitation, charge-transporting layers, charge-blocking layers and charge injection layers. The device may contain more than one light-emitting layer.

Exemplary OLED structures including one or more further layers include the following:

Anode/Hole-injection layer/Light-emitting layer/Cathode
Anode/Hole transporting layer/Light-emitting layer/Cathode
Anode/Hole-injection layer/Hole-transporting layer/Light-emitting layer/Cathode
Anode/Hole-injection layer/Hole-transporting layer/Light-emitting layer/Electron-transporting layer/Cathode.

Light-emitting layer 103 may contain a host material and a phosphorescent compound of formula (I). Light-emitting layer may contain further light-emitting compounds, for example further phosphorescent or fluorescent light-emitting materials having a colour of emission differing from that of the compound of formula (I). The host material may combine holes injected from the anode and electrons injected from the cathode to form singlet and triplet excitons. The triplet excitons at least may be transferred to the phosphorescent compound, and decay to produce phosphorescence.

Preferably, light emitted from a composition of a host and a compound of formula (I) is substantially all from the compound of formula (I).

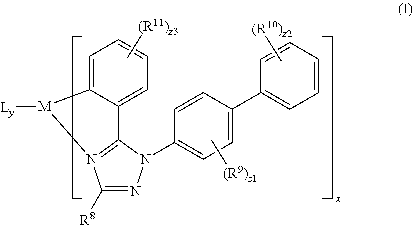

### Phosphorescent Compound

Metal M of the phosphorescent compound of formula (I) may be any suitable transition metal, for example a transition metal of the second or third row of the d-block elements (Period 5 and Period 6, respectively, of the Periodic Table). Exemplary metals include Ruthenium, Rhodium, Palladium, Silver, Tungsten, Rhenium, Osmium, Iridium, Platinum and Gold. Preferably, M is iridium.

Substituents may be provided on the compound of formula (I).

One or both of the phenyl groups of the biphenyl group bound to the triazole ring of the compound of formula (I) may be substituted. Exemplary biphenyl groups include the following:

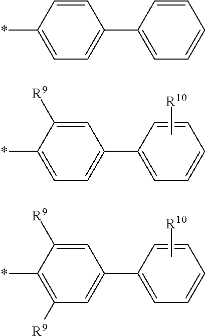

wherein * represents a position through which the biphenyl group is linked to the triazole ring of the compound of formula (I). Preferably, groups R⁹ and R¹⁰ are each independently selected from C₁₋₂₀ alkyl.

The presence of one or two substituents R⁹ on one or both of the phenyl carbon atoms adjacent to the linking position of the biphenyl group may cause a twist between the biphenyl group and the triazole ring, which may limit the extent of conjugation between the biphenyl and the triazole ring. Limiting the extent of conjugation between the biphenyl and the triazole ring may limit a shift towards a longer wavelength that substitution of the triazole with a biphenyl group may otherwise cause.

An alkyl substituent R¹⁰ may enhance solubility of the compound of formula (I) in non-polar solvents.

Optionally, R⁸ is selected from the group consisting of:

substituted or unsubstituted aryl or heteroaryl, optionally unsubstituted phenyl or phenyl substituted with one or more C₁₋₂₀ alkyl groups; and
branched, linear or cyclic C₁₋₂₀ alkyl wherein non-adjacent C atoms of the C₁₋₂₀ alkyl may be replaced with —O—, —S—, —NR³—, —SiR³₂— or —COO— and one or more H atoms may be replaced with F, wherein R³ is H or a substituent, optionally C₁₋₂₀ alkyl or phenyl that may be unsubstituted or substituted with one or more C₁₋₂₀ alkyl groups.

The phenyl group of the phenyltriazole ligand of compounds of formula (I) may be substituted with one or more substituents R¹¹.

Optionally, R¹¹ in each occurrence is independently selected from the group consisting of R¹⁴, OR¹⁴, SR¹⁴, NR¹⁴₂, PR¹⁴₂, P(═O)R¹⁴₂, wherein R¹⁴ in each occurrence is independently selected from the group consisting of C₁₋₄₀ hydrocarbyl, optionally C₁₋₂₀ alkyl and phenyl that may be unsubstituted or substituted with one or more C₁₋₂₀ alkyl groups.

Two substituents R¹¹ may be linked to form a ring structure. The ring structure formed by linking two substituents R11 may be a monocyclic or polycyclic ring fused to the phenyl group of the phenyltriazole ligand. The monocyclic or polycyclic ring may be unsubstituted or substituted with one or more substituents, for example one or more C₁₋₂₀ alkyl groups.

In a preferred embodiment, the phenyl of the phenyltriazole ligand is substituted with an aromatic group, preferably a phenyl group, that may itself be unsubstituted or substituted with one or more substituents, for example one or more C₁₋₂₀ alkyl groups.

Optionally, the compound of formula (I) has formula (Ia) or (Ib):

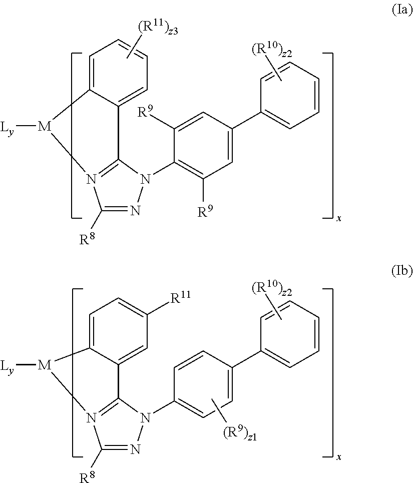

Optionally, z3 is at least 2 and two groups z3 are linked to form a monocyclic or polycyclic ring. Optionally, the compound of formula (I) has formula (Ic) or (Id)

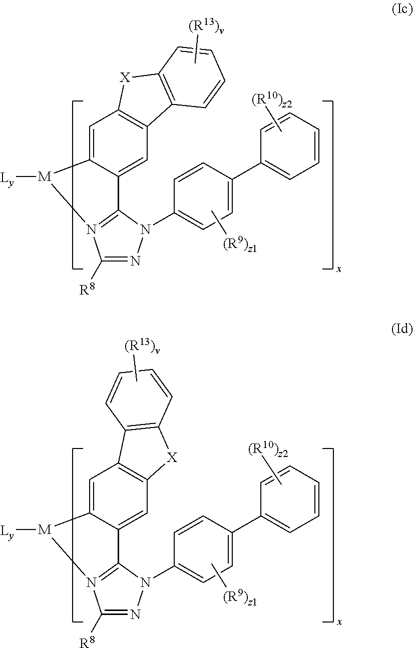

wherein X in each occurrence is O, S, NR¹⁴, PR¹⁴, P(═O)R¹⁴, SiR¹⁴₂ or CR¹⁴₂, and v is 0 or a positive integer.

Exemplary ligands include the following:

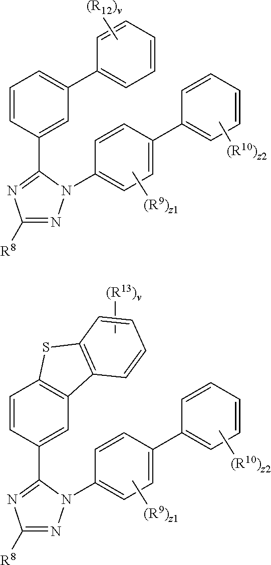

wherein R¹² independently in each occurrence is a substituent and v independently in each occurrence is 0 or a positive integer. Preferably, R¹² in each occurrence is independently selected from the group consisting of branched, linear or cyclic C₁₋₂₀ alkyl wherein non-adjacent C atoms of the C₁₋₂₀ alkyl may be replaced with —O—, —S—, —NR¹²—, —SiR¹²₂— or —COO— and one or more H atoms may be replaced with F.

The metal complex of formula (I) may be homoleptic complex in which y is 0, i.e. the value of x satisfies the valency of the metal M, or a heteroleptic complex in which y is at least 1.

In the case where the metal complex is heteroleptic, the ligands may differ in one or more of:
(i) the groups directly coordinated to metal M;
(ii) the number of substituents on the coordinating groups;
(iii) the position of substituents on the coordinating groups; and
(iv) the structure of substituents on the coordinating groups.
   y of formula (I) may be 0 or a positive integer. If y=0 then x may be 3.

If y is a positive integer then exemplary ligands L of formula (I) include unsubstituted phenyltriazole, or phenyltriazole substituted with one or more C₁₋₂₀ alkyl groups, unsubstituted phenylimidazole or phenylimidazole substituted with one or more C₁₋₂₀ alkyl groups, unsubstituted phenylpyrazole or phenylpyrazole substituted with one or more C₁₋₂₀ alkyl groups, and unsubstituted imidazo-phenanthridine or imidazo-phenanthridine substituted with one or more C₁₋₂₀ alkyl groups and ancillary ligands, for example tetrakis-(pyrazol-1-yl)borate, 2-carboxypyridyl and diketonates, for example acetylacetonate.

Exemplary compounds of formula (I) include the following:

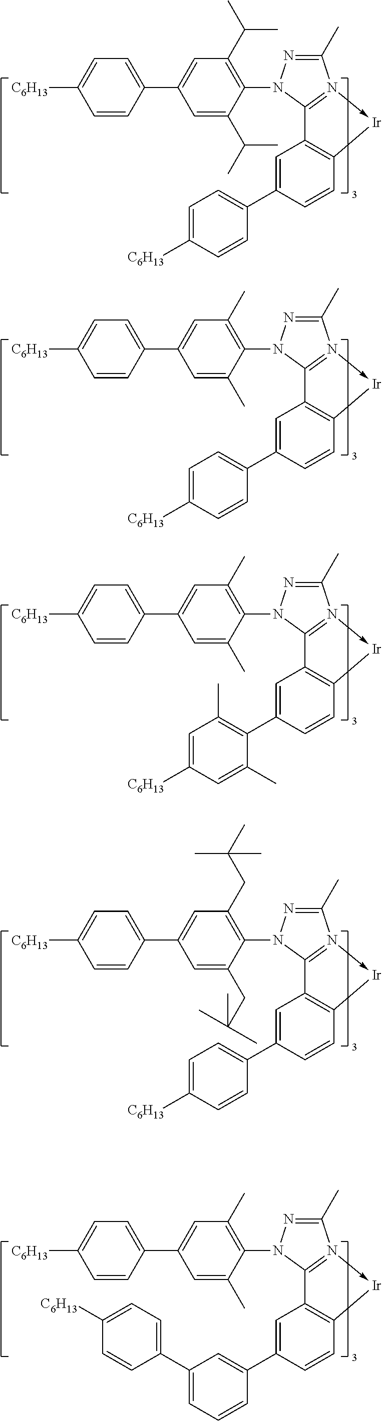

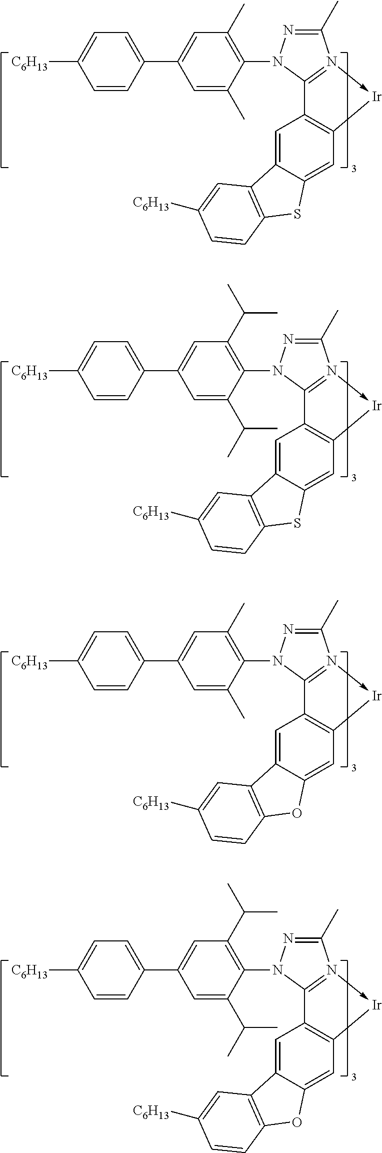

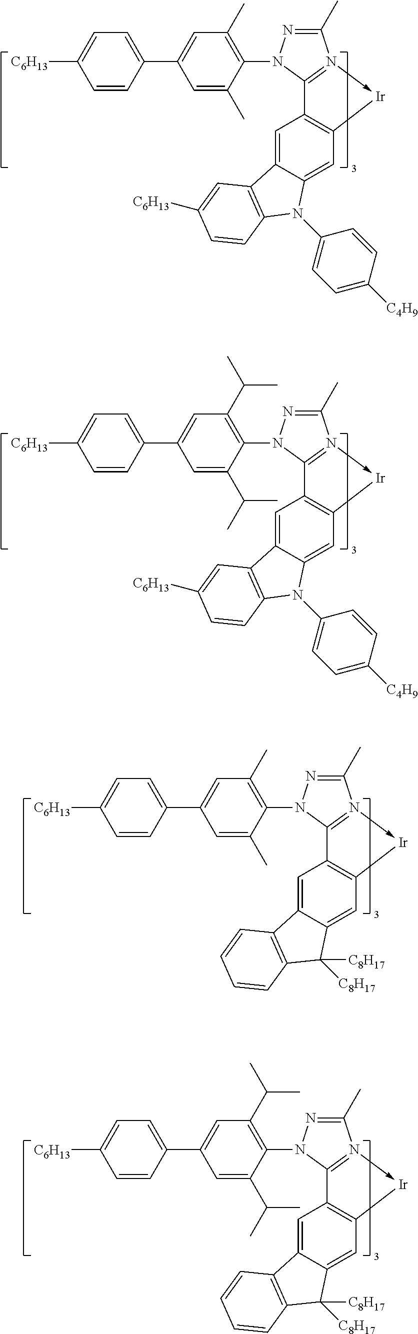

Compounds of formula (I) preferably have a photoluminescence spectrum with a peak in the range of 400-490 nm, optionally 420-490 nm, optionally 460-480 nm.

### Host Material

The host material has a triplet excited state energy level T₁ that is no more than 0.1 eV lower than, and preferably at least the same as or higher than, the phosphorescent compound of formula (I) in order to allow transfer of triplet excitons from the host material to the phosphorescent compound of formula (I).

The triplet excited state energy levels of the host material and the phosphorescent compound may be determined from their respective phosphorescence spectra.

FIG. 2 illustrates energy levels for the light-emitting device of FIG. 1 in which the light-emitting layer 3 contains a light-emitting composition of an phosphorescent compound of formula (I), P, and an electron-transporting host material, H, such as a triazine-containing host as described in more detail with reference to Formula (VII) below.

The host material has a HOMO level H_{H} and a LUMO level L_{H}. The phosphorescent emitter has HOMO level H_{P} and LUMO level L_{P}. An exciplex may form between the HOMO of the phosphorescent emitter and the LUMO of the host material, particularly if this HOMO-LUMO gap L_{H}-H_{P} is too small. Preferably, the HOMO level of light-emitting materials is deeper (further away from the vacuum level) than 5.0 eV in order to maintain a relatively large emitter HOMO-host LUMO gap and minimise exciplex formation. Preferably, the emitter HOMO-host LUMO gap is greater than 2.4 eV, and is optionally up to 3.5 eV. The present inventors have found that this gap is typically large enough to avoid exciplex formation when compounds of formula (I) are used with an electron-transporting host.

The host material may be a polymer or a non-polymeric compound.

The compound of formula (I) may be mixed with the host material or may be covalently bound to the host material. In the case where the host material is a polymer, the metal complex may be provided as a main chain repeat unit, a side group of a repeat unit, or an end group of the polymer.

In the case where the compound of formula (I) is provided as a side group, the metal complex may be directly bound to a main chain of the polymer or spaced apart from the main chain by a spacer group. Exemplary spacer groups include C₁₋₂₀ alkyl groups, aryl-C₁₋₂₀ alkyl groups and C₁₋₂₀ alkoxy groups. The polymer main chain or spacer group may be bound to phenyltriazole; or (if present) another ligand of the compound of formula (I).

If the compound of formula (I) is bound to a polymer comprising conjugated repeat units then it may be bound to the polymer such that there is no conjugation between the conjugated repeat units and the compound of formula (I), or such that the extent of conjugation between the conjugated repeat units and the compound of formula (I) is limited.

If the compound of formula (I) is mixed with a host material then the host:emitter weight ratio may be in the range of 50-99.5:50-0.5.

If the compound of formula (I) is bound to a polymer then repeat units or end groups containing a compound of formula (I) may form 0.5-20 mol percent, more preferably 1-10 mol percent of the polymer.

Optionally, the energy gap between the HOMO of the host material and the LUMO of the compound of formula (I) is greater than 2.2 eV.

Exemplary host polymers include polymers having a non-conjugated backbone with charge-transporting groups pendant from the non-conjugated backbone, for example poly(9-vinylcarbazole), and polymers comprising conjugated repeat units in the backbone of the polymer. If the backbone of the polymer comprises conjugated repeat units then the extent of conjugation between repeat units in the polymer backbone may be limited in order to maintain a triplet energy level of the polymer that is no lower than that of the phosphorescent compound of formula (I).

Exemplary repeat units of a conjugated polymer include optionally substituted monocyclic and polycyclic arylene repeat units as disclosed in for example, Adv. Mater. 2000 12(23) 1737-1750 and include: 1,2-, 1,3- and 1,4-phenylene repeat units as disclosed in J. Appl. Phys. 1996, 79, 934; 2,7-fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

One exemplary class of arylene repeat units is optionally substituted fluorene repeat units, such as repeat units of formula IV:

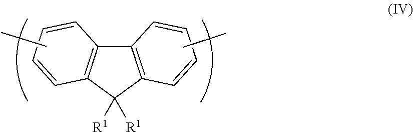

wherein R¹ in each occurrence is the same or different and is H or a substituent, and wherein the two groups R¹ may be linked to form a ring.

Each R¹ is preferably a substituent, and each R¹ may independently be selected from the group consisting of:
optionally substituted alkyl, optionally C₁₋₂₀ alkyl, wherein one or more non-adjacent C atoms may be replaced with optionally substituted aryl or heteroaryl, O, S, substituted N, C═O or —COO—;
optionally substituted aryl or heteroaryl;
a linear or branched chain of aryl or heteroaryl, each of which groups may independently be substituted, for example a group of formula -(Ar⁶)ᵣ as described below with reference to formula (VII); and
a crosslinkable-group, for example a group comprising a double bond such and a vinyl or acrylate group, or a benzocyclobutane group.
In the case where R¹ comprises aryl or heteroaryl ring system, or a linear or branched chain of aryl or heteroaryl ring systems, the or each aryl or heteroaryl ring system may be substituted with one or more substituents R³ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR⁵₂, OR⁵, SR⁵, and
fluorine, nitro and cyano;
   wherein each R⁴ is independently alkyl, for example C₁₋₂₀ alkyl, in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups.

Optional substituents for the fluorene unit, other than substituents R¹, are preferably selected from the group consisting of alkyl, for example C₁₋₂₀ alkyl, wherein one or more non-adjacent C atoms may be replaced with O, S, NH or substituted N, C═O and —COO—, optionally substituted aryl, optionally substituted heteroaryl, alkoxy, alkylthio, fluorine, cyano and arylalkyl. Particularly preferred substituents include C₁₋₂₀ alkyl and substituted or unsubstituted aryl, for example phenyl. Optional substituents for the aryl include one or more C₁₋₂₀ alkyl groups.

Where present, substituted N may independently in each occurrence be NR⁶ wherein R⁶ is alkyl, optionally C₁₋₂₀ alkyl, or optionally substituted aryl or heteroaryl. Optional substituents for aryl or heteroaryl R⁶ may be selected from R⁴ or R⁵.

Preferably, each R¹ is selected from the group consisting of C₁₋₂₀ alkyl and optionally substituted phenyl. Optional substituents for phenyl include one or more C₁₋₂₀ alkyl groups.

If the compound of formula (I) is provided as a side-chain of the polymer then at least one R¹ may comprise a compound of formula (I) that is either bound directly to the 9-position of the fluorene unit or spaced apart from the 9-position by a spacer group.

The repeat unit of formula (IV) may be a 2,7-linked repeat unit of formula (IVa):

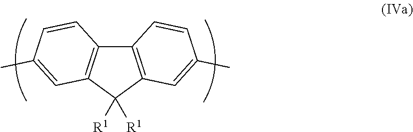

Optionally, the repeat unit of formula (IVa) is not substituted in a position adjacent to the 2- or 7-positions.

The extent of conjugation of repeat units of formulae (IV) may be limited by (a) linking the repeat unit through the 3- and/or 6-positions to limit the extent of conjugation across the repeat unit, and/or (b) substituting the repeat unit with one or more further substituents R¹ in or more positions adjacent to the linking positions in order to create a twist with the adjacent repeat unit or units, for example a 2,7-linked fluorene carrying a C₁₋₂₀ alkyl substituent in one or both of the 3- and 6-positions.

Another exemplary class of arylene repeat units is phenylene repeat units, such as phenylene repeat units of formula (V):

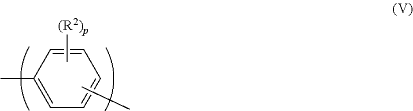

wherein p is 0, 1, 2, 3 or 4, optionally 1 or 2, and R² independently in each occurrence is a substituent, optionally a substituent R¹ as described above, for example C₁₋₂₀ alkyl, and phenyl that is unsubstituted or substituted with one or more C₁₋₂₀ alkyl groups.

The repeat unit of formula (V) may be 1,4-linked, 1,2-linked or 1,3-linked.

If the repeat unit of formula (V) is 1,4-linked and if p is 0 then the extent of conjugation of repeat unit of formula (V) to one or both adjacent repeat units may be relatively high.

If p is at least 1, and/or the repeat unit is 1,2- or 1,3 linked, then the extent of conjugation of repeat unit of formula (V) to one or both adjacent repeat units may be relatively low. In one preferred arrangement, the repeat unit of formula (V) is 1,3-linked and p is 0, 1, 2 or 3. In another preferred arrangement, the repeat unit of formula (V) has formula (Va):

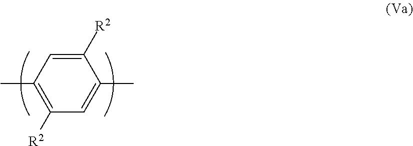

Arylene repeat units such as repeat units of formula (IV) and (V) may be fully conjugated with aromatic or heteroaromatic group of adjacent repeat units. Additionally or alternatively, a host polymer may contain a conjugation-breaking repeat unit that completely breaks conjugation between repeat units adjacent to the conjugation-breaking repeat unit. An exemplary conjugation-breaking repeat unit has formula (IX):

-(Ar⁷-Sp¹-Ar⁷)- (IX)

wherein Ar⁷ independently in each occurrence represents an aromatic or heteroaromatic group that may be unsubstituted or substituted with one or more substituents, and Sp¹ represents a spacer group comprising at least one sp³ hybridised carbon atom separating the two groups Ar⁷. Preferably, each Ar⁷ is phenyl and Sp¹ is a C₁₋₁₀ alkyl group. Substituents for Ar⁷ may be selected from groups R² described above with reference to formula (V), and are preferably selected from C₁₋₂₀ alkyl.

A host polymer may comprise charge-transporting units CT that may be hole-transporting units or electron transporting units.

A hole transporting unit may have a low electron affinity (2 eV or lower) and low ionisation potential (5.8 eV or lower, preferably 5.7 eV or lower, more preferred 5.6 eV or lower).

An electron-transporting unit may have a high electron affinity (1.8 eV or higher, preferably 2 eV or higher, even more preferred 2.2 eV or higher) and high ionisation potential (5.8 eV or higher) Suitable electron transport groups include groups disclosed in, for example, Shirota and Kageyama, Chem. Rev. 2007, 107, 953-1010.

Electron affinities and ionisation potentials may be measured by cyclic voltammetry (CV) wherein the working electrode potential is ramped linearly versus time.

When cyclic voltammetry reaches a set potential the working electrode's potential ramp is inverted. This inversion can happen multiple times during a single experiment. The current at the working electrode is plotted versus the applied voltage to give the cyclic voltammogram trace.

Apparatus to measure HOMO or LUMO energy levels by CV may comprise a cell containing a tert-butyl ammonium perchlorate/or tertbutyl ammonium hexafluorophosphate solution in acetonitrile, a glassy carbon working electrode where the sample is coated as a film, a platinium counter electrode (donor or acceptor of electrons) and a reference glass electrode no leak Ag/AgCl. Ferrocene is added in the cell at the end of the experiment for calculation purposes. (Measurement of the difference of potential between Ag/AgCl/ferrocene and sample/ferrocene).

### Method and Settings:

3 mm diameter glassy carbon working electrode
Ag/AgCl/no leak reference electrode
Pt wire auxiliary electrode
0.1 M tetrabutylammonium hexafluorophosphate in acetonitrile
LUMO=4.8−ferrocene (peak to peak maximum average)+onset

Sample: 1 drop of 5 mg/mL in toluene spun @3000 rpm LUMO (reduction) measurement: A good reversible reduction event is typically observed for thick films measured at 200 mV/s and a switching potential of −2.5V. The reduction events should be measured and compared over 10 cycles, usually measurements are taken on the 3^{rd} cycle. The onset is taken at the intersection of lines of best fit at the steepest part of the reduction event and the baseline.

Exemplary hole-transporting units CT include optionally substituted (hetero)arylamine repeat units, for example repeat units of formula (VI):

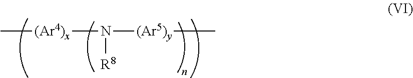

wherein Ar⁴ and Ar⁵ in each occurrence are independently selected from optionally substituted aryl or heteroaryl, n is greater than or equal to 1, preferably 1 or 2, R⁸ is H or a substituent, preferably a substituent, and x and y are each independently 1, 2 or 3.

Ar⁴ and Ar⁵ may each independently be a monocyclic or fused ring system.

R⁸, which may be the same or different in each occurrence when n>1, is preferably selected from the group consisting of alkyl, for example C₁₋₂₀ alkyl, Ar⁶, a branched or linear chain of Ar⁶ groups, or a crosslinkable unit that is bound directly to the N atom of formula (VI) or spaced apart therefrom by a spacer group, wherein Ar⁶ in each occurrence is independently optionally substituted aryl or heteroaryl. Exemplary spacer groups are as described above, for example C₁₋₂₀ alkyl, phenyl and phenyl-C₁₋₂₀ alkyl.

Ar⁶ groups may be substituted with one or more substituents as described below. An exemplary branched or linear chain of Ar⁶ groups may have formula -(Ar⁶)ᵣ, wherein Ar⁶ in each occurrence is independently selected from aryl or heteroaryl and r is at least 1, optionally 1, 2 or 3. An exemplary branched chain of Ar⁶ groups is 3,5-diphenylbenzene.

Any of Ar⁴, Ar⁵ and Ar⁶ may independently be substituted with one or more substituents.

Preferred substituents are selected from the group R³ consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR⁵₂, OR⁵, SR⁵,
fluorine, nitro and cyano;
   wherein each R⁴ is independently alkyl, for example C₁₋₂₀ alkyl, in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups.

Any of Ar⁴, Ar⁵ and, if present, Ar⁶ in the repeat unit of Formula (VI) may be linked by a direct bond or a divalent linking atom or group to another of Ar⁴, Ar⁵ and Ar⁶. Preferred divalent linking atoms and groups include O, S; substituted N; and substituted C.

Where present, substituted N or substituted C of R³, R⁴ or of the divalent linking group may independently in each occurrence be NR⁶ or CR⁶₂ respectively wherein R⁶ is alkyl or optionally substituted aryl or heteroaryl. Optional substituents for aryl or heteroaryl R⁶ may be selected from R⁴ or R⁵.

In one preferred arrangement, R⁸ is Ar⁶ and each of Ar⁴, Ar⁵ and Ar⁶ are independently and optionally substituted with one or more C₁₋₂₀ alkyl groups.

Particularly preferred units satisfying Formula (VI) include units of Formulae 1-4:

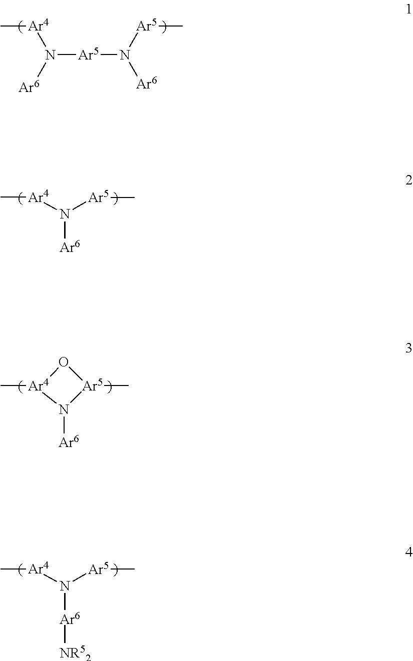

Where present, preferred substituents for Ar⁶ include substituents as described for Ar⁴ and Ar⁵, in particular alkyl and alkoxy groups.

Ar⁴, Ar⁵ and Ar⁶ are preferably phenyl, each of which may independently be substituted with one or more substituents as described above.

In another preferred arrangement, Ar⁴, Ar⁵ and Ar⁶ are phenyl, each of which may be substituted with one or more C₁₋₂₀ alkyl groups, and r=1.

In another preferred arrangement, Ar⁴ and Ar⁵ are phenyl, each of which may be substituted with one or more C₁₋₂₀ alkyl groups, and R⁸ is 3,5-diphenylbenzene wherein each phenyl may be substituted with one or more C₁₋₂₀ alkyl groups.

In another preferred arrangement, n, x and y are each 1 and Ar⁴ and Ar⁵ are phenyl linked by an oxygen atom to form a phenoxazine ring.

Triazines form an exemplary class of electron-transporting units, for example optionally substituted di- or tri-(hetero)aryltriazine attached as a side group through one of the (hetero)aryl groups. Other exemplary electron-transporting units are pyrimidines and pyridines; sulfoxides and phosphine oxides; benzophenones; and boranes, each of which may be unsubstituted or substituted with one or more substituents, for example one or more C₁₋₂₀ alkyl groups.

Exemplary electron-transporting units CT have formula (VII):

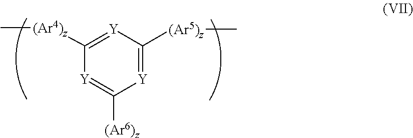

wherein Ar⁴, Ar⁵ and Ar⁶ are as described with reference to formula (VI) above, and may each independently be substituted with one or more substituents described with reference to Ar⁴, Ar⁵ and Ar⁶, and z in each occurrence is independently at least 1, optionally 1, 2 or 3 and Y is N or CR⁷, wherein R⁷ is H or a substituent, preferably H or C₁₋₁₀ alkyl. Preferably, Ar⁴, Ar⁵ and Ar⁶ of formula (VII) are each phenyl, each phenyl being optionally and independently substituted with one or more C₁₋₂₀ alkyl groups.

In one preferred embodiment, all 3 groups Y are N.

If all 3 groups Y are CR⁷ then at least one of Ar¹, Ar² and Ar³ is preferably a hetero aromatic group comprising N.

Each of Ar⁴, Ar⁵ and Ar⁶ may independently be substituted with one or more substituents. In one arrangement, Ar⁴, Ar⁵ and Ar⁶ are phenyl in each occurrence. Exemplary substituents include R³ as described above with reference to formula (VII), for example C₁₋₂₀ alkyl or alkoxy.

Ar⁶ of formula (VII) is preferably phenyl, and is optionally substituted with one or more C₁₋₂₀ alkyl groups or a crosslinkable unit. The crosslinkable unit may or may not be a unit of formula (I) bound directly to Ar⁶ or spaced apart from Ar⁶ by a spacer group.

The charge-transporting units CT may be provided as distinct repeat units formed by polymerising a corresponding monomer. Alternatively, the one or more CT units may form part of a larger repeat unit, for example a repeat unit of formula (VIII):

(Ar³)_{q}-Sp-CT-Sp-(Ar³)_{q} (VIII)

wherein CT represents a conjugated charge-transporting group; each Ar³ independently represents an unsubstituted or substituted aryl or heteroaryl; q is at least 1; and each Sp independently represents a spacer group forming a break in conjugation between Ar³ and CT.

Sp is preferably a branched, linear or cyclic C₁₋₂₀ alkyl group.

Exemplary CT groups may be units of formula (VI) or (VII) described above.

Ar³ is preferably an unsubstituted or substituted aryl, optionally an unsubstituted or substituted phenyl or fluorene. Optional substituents for Ar³ may be selected from R³ as described above, and are preferably selected from one or more C₁₋₂₀ alkyl substituents.

q is preferably 1.

The polymer may comprise repeat units that block or reduce conjugation along the polymer chain and thereby increase the polymer bandgap. For example, the polymer may comprise units that are twisted out of the plane of the polymer backbone, reducing conjugation along the polymer backbone, or units that do not provide any conjugation path along the polymer backbone. Exemplary repeat units that reduce conjugation along the polymer backbone are substituted or unsubstituted 1,3-substituted phenylene repeat units, and 1,4-phenylene repeat substituted with a C₁₋₂₀ alkyl group in the 2- and/or 5-position, as described above with reference to formula (V).

The molar percentage of charge transporting repeat units in the polymer, for example repeat units of formula (VI), (VII), (VIII), may be in the range of up to 75 mol %, optionally in the range of up to 50 mol % of the total number of repeat units of the polymer.

### White OLED

An OLED of the invention may be a white OLED containing a blue light-emitting compound of formula (I) and one or more further light-emitting materials having a colour of emission such that light emitted from the device is white. Further light-emitting materials include red and green light-emitting materials that may be fluorescent or phosphorescent.

The one or more further light-emitting materials may present in the same light-emitting layer as the compound of formula (I) or may be provided in one or more further light-emitting layers of the device.

The light emitted from a white OLED may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-600K.

A green emitting material may have a photoluminescent spectrum with a peak in the range of more than 490 nm up to 580 nm, optionally more than 490 nm up to 540 nm

A red emitting material may optionally have a peak in its photoluminescent spectrum of more than 580 nm up to 630 nm, optionally 585 nm up to 625 nm.

### Polymer Synthesis

Preferred methods for preparation of conjugated polymers, such as polymers comprising one or more of repeat units of formulae (IV), (V), (VI), (VII), (VIII) and (IX) as described above, comprise a “metal insertion” wherein the metal atom of a metal complex catalyst is inserted between an aryl or heteroaryl group and a leaving group of a monomer. Exemplary metal insertion methods are Suzuki polymerisation as described in, for example, WO 00/53656 and Yamamoto polymerisation as described in, for example, T. Yamamoto, “Electrically Conducting And Thermally Stable pi-Conjugated Poly(arylene)s Prepared by Organometallic Processes”, Progress in Polymer Science 1993, 17, 1153-1205. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units illustrated throughout this application may be derived from a monomer carrying suitable leaving groups. Likewise, an end group or side group may be bound to the polymer by reaction of a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular copolymers may be prepared when both reactive groups of a first monomer are boron and both reactive groups of a second monomer are halogen.

As alternatives to halides, other leaving groups capable of participating in metal insertion include sulfonic acids and sulfonic acid esters such as tosylate, mesylate and triflate.

### Charge Transporting and Charge Blocking Layers

A hole transporting layer may be provided between the anode and the light-emitting layer or layers. Likewise, an electron transporting layer may be provided between the cathode and the light-emitting layer or layers.

Similarly, an electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

A charge-transporting layer or charge-blocking layer may be crosslinked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group. The crosslinkable group may be provided as a substituent pendant from the backbone of a charge-transporting or charge-blocking polymer. Following formation of a charge-transporting or charge blocking layer, the crosslinkable group may be crosslinked by thermal treatment or irradiation.

If present, a hole transporting layer located between the anode and the light-emitting layers preferably has a HOMO level of less than or equal to 5.5 eV, more preferably around 4.8-5.5 eV as measured by cyclic voltammetry. The HOMO level of the hole transport layer may be selected so as to be within 0.2 eV, optionally within 0.1 eV, of an adjacent layer (such as a light-emitting layer) in order to provide a small barrier to hole transport between these layers.

If present, an electron transporting layer located between the light-emitting layers and cathode preferably has a LUMO level of around 2.5-3.5 eV as measured by square wave cyclic voltammetry. A layer of a silicon monoxide or silicon dioxide or other thin dielectric layer having thickness in the range of 0.2-2 nm may be provided between the light-emitting layer nearest the cathode and the cathode. HOMO and LUMO levels may be measured using cyclic voltammetry.

A hole transporting layer may contain a hole-transporting (hetero)arylamine, such as a homopolymer or copolymer comprising hole transporting repeat units of formula (VI). Exemplary copolymers comprise repeat units of formula (VI) and optionally substituted (hetero)arylene co-repeat units, such as phenyl, fluorene or indenofluorene repeat units as described above, wherein each of said (hetero)arylene repeat units may optionally be substituted with one or more substituents such as alkyl or alkoxy groups. Specific co-repeat units include fluorene repeat units of formula (IV) and optionally substituted phenylene repeat units of formula (V) as described above. A hole-transporting copolymer containing repeat units of formula (VI) may contain 25-95 mol % of repeat units of formula (VI).

An electron transporting layer may contain a polymer comprising a chain of optionally substituted arylene repeat units, such as a chain of fluorene repeat units.

### Hole Injection Layers

A conductive hole injection layer, which may be formed from a conductive organic or inorganic material, may be provided between the anode and the light-emitting layer or layers to assist hole injection from the anode into the layer or layers of semiconducting polymer. A hole transporting layer may be used in combination with a hole injection layer.

Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx, MoOx and RuOx as disclosed in Journal of Physics D: Applied Physics (1996), 29(11), 2750-2753.

### Cathode

The cathode is selected from materials that have a workfunction allowing injection of electrons into the light-emitting layer or layers. Other factors influence the selection of the cathode such as the possibility of adverse interactions between the cathode and the light-emitting materials. The cathode may consist of a single material such as a layer of aluminium. Alternatively, it may comprise a plurality of metals, for example a bilayer of a low workfunction material and a high workfunction material such as calcium and aluminium as disclosed in WO 98/10621. The cathode may contain a layer containing elemental barium, for example as disclosed in WO 98/57381, Appl. Phys. Lett. 2002, 81(4), 634 and WO 02/84759. The cathode may contain a thin (e.g. 1-5 nm thick) layer of metal compound between the light-emitting layer(s) of the OLED and one or more conductive layers of the cathode, such as one or more metal layers. Exemplary metal compounds include an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen. Accordingly, the substrate 1 preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Solution Processing

Suitable solvents for forming solution processable formulations of the light-emitting metal complex of formula (I) and compositions thereof may be selected from common organic solvents, such as mono- or poly-alkylbenzenes such as toluene and xylene.

Exemplary solution deposition techniques for forming a light-emitting layer containing a compound of formula (I) include printing and coating techniques such spin-coating, dip-coating, roll-to-roll coating or roll-to-roll printing, doctor blade coating, slot die coating, gravure printing, screen printing and inkjet printing.

Coating methods, such as those described above, are particularly suitable for devices wherein patterning of the light-emitting layer or layers is unnecessary—for example for lighting applications or simple monochrome segmented displays.

Printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

The same coating and printing methods may be used to form other layers of an OLED including (where present) a hole injection layer, a charge transporting layer and a charge blocking layer.

### EXAMPLES

### Comparative Metal Complex 1

Comparative Metal Complex 1 was prepared according to the method described in WO 2004/101707.

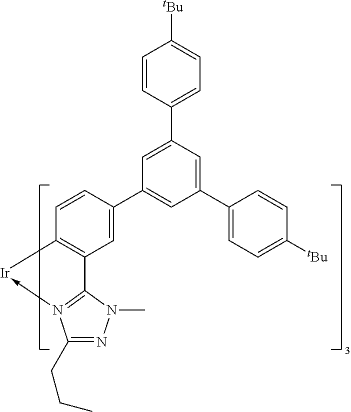

### Comparative Metal Complex 1

### Stage 1:

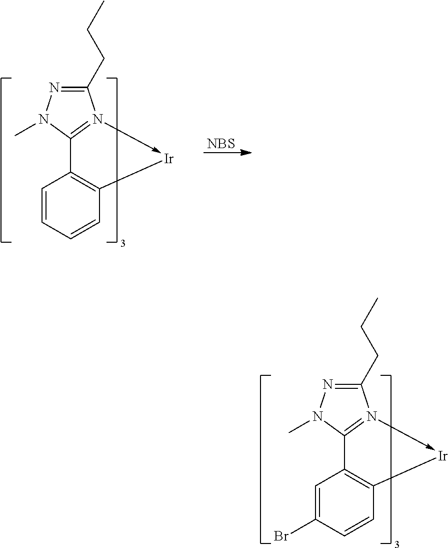

fac-Tris(1-methyl-5-phenyl-3-propyl-[1,2,4]triazolyl)iridium(III) (1.1 g) (Shih-Chun Lo et al., Chem. Mater. 2006, 18, 5119-5129) (1.1 g) was dissolved in DCM (100 mL) under a flow of nitrogen. N-Bromosuccinimide (0.93 g) was added as a solid and the mixture was stirred at room temperature with protection from light. After 24 h HPLC analysis showed ˜94% product and ˜6% dibromide intermediate. A further 50 mg of NBS was added and stirring continued for 16 hours. A further 50 mg of NBS was added and stirring continued for 24 h. HPLC indicated over 99% product. Warm water was added and stirred for 0.5 h. The layers were separated and the organic layer passed through a plug of celite eluting with DCM.

The filtrate was concentrated to ˜15 mL and hexane was added to the DCM solution to precipitate the product as a yellow solid in 80% yield.

### Stage 2:

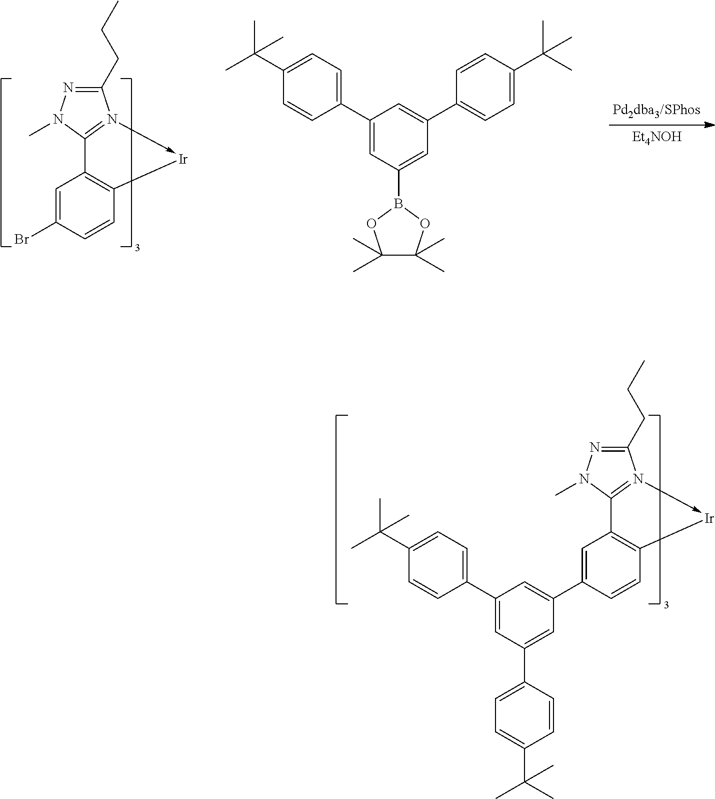

Stage 1 material (8.50 g) and 3,5-bis(4-tert-butylphenyl)phenyl-1-boronic acid pinacol ester (15.50 g) were dissolved in toluene (230 mL). The solution was purged with nitrogen for 1 h before 2-dicyclohexylphosphino-2′,6′-dimethoxybiphenyl (66 mg) and tris(dibenzylidene)dipalladium (75 mg) were added using 10 mL of nitrogen-purged toluene. A 20 wt % solution of tetraethylammonium hydroxide in water (60 mL) was added in one portion and the mixture as stirred for 20 h with the heating bath set to 105° C. T.L.C. analysis indicated all the stage material had been consumed and only one fluorescent spot was observed. The reaction mixture was cooled and filtered into a separating funnel. The layers were separated and the aqueous layer extracted with toluene. The organic extracts were washed with water, dried with magnesium sulphate, filtered and concentrated to yield the crude product as a yellow/orange solid. Pure compound was obtained by column chromatography eluting with a gradient of ethyl acetate in hexanes followed by precipitation from DCM/methanol. HPLC indicated a purity of 99.75% and a yield of 80% (11.32 g). ¹H NMR (referenced to CDCl3): 7.83 (3H, d), 7.76 (6H, s), 7.73 (3H, s) 7.63 (12H, d) 7.49 (12H, d), 7.21 (3H, dd), 6.88 (3H, d), 4.28 (9H, s), 2.25 (3H, m), 1.98 (3H, m), 1.4-1.5 (57H, m), 1.23 (3H, m), 0.74 (9H, t)

### Comparative Metal Complex 2

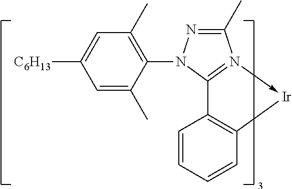

Comparative Metal Complex 2, illustrated above, was prepared according to the following reaction scheme:

### Synthesis of Ligand 1:

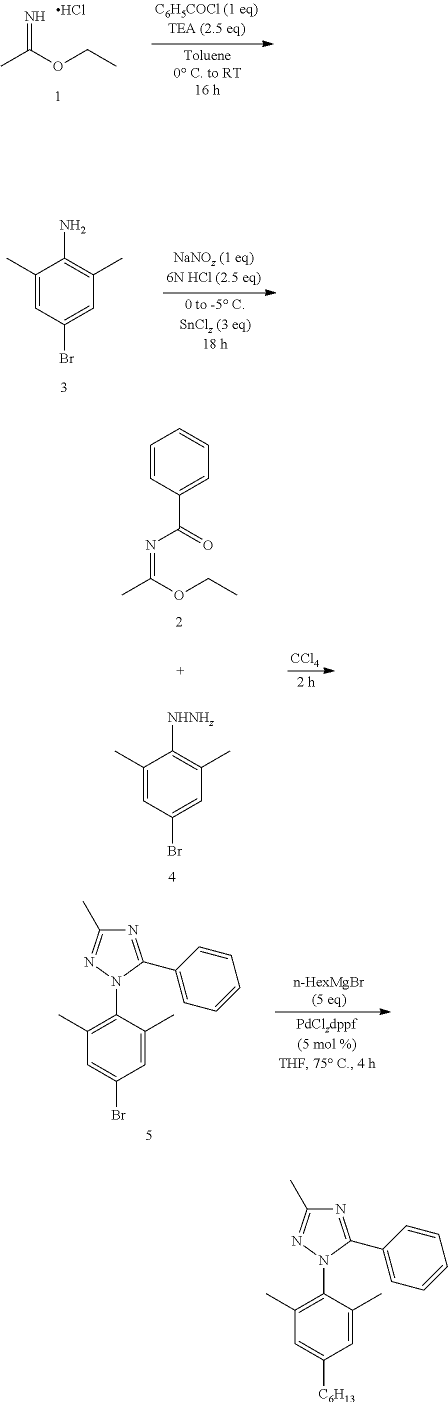

### Step 1—Synthesis of N-(1-Ethoxy-ethylidene)benzamide (2)

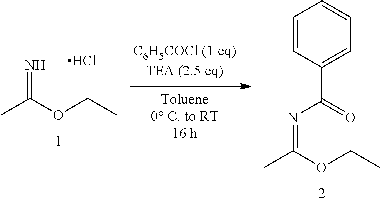

| S. | | Quantity | Vol. | | | |
|---|---|---|---|---|---|---|
| No | Reagent | (g) | (mL) | MW | Moles | Eq. |
| 1 | Ethylacetimidate | 60 | | 123.58 | 0.485 | 1 |
| | hydrochloride | | | | | |
| 2 | Triethylamine | | 170 | 101.19 | 1.213 | 2.5 |
| 3 | Benzoyl chloride | | 56.5 | 140.57 | 0.485 | 1 |
| 4 | Toluene | | 900 | | | |

### Apparatus Set-Up:

A 2 L 3-necked round-bottomed flask, equipped with a mechanical overhead stirrer, condenser, nitrogen inlet and exhaust.

### Experimental Procedure:

1) To the suspension of ethylacetimidate hydrochloride (1) (60 g, 0.485 mol) in toluene, triethylamine (170 mL, 1.213 mol) was added at 0° C. and stirred for an hour.
2) Benzoyl chloride (56.5 mL, 0.485 mol) in toluene (50 mL) was slowly added to the reaction mixture at 0° C.
3) The reaction mixture was allowed to stir at RT for 16 h. Then the mixture was filtered and washed with toluene.
4) The filtrate was concentrated to yield 46 g (49.7%) of N-(1-Ethoxy-ethylidene)-benzamide (2) as brown oily liquid. It was taken without further purification.

### Analytical Specifications

¹H-NMR (400 MHz, CDCl₃): δ [ppm] 1.39 (t, J=6.8 Hz, 3H), 2.07 (s, 3H), 4.31 (q, J=6.8 Hz, 2H), 7.42-7.48 (m, 2H), 7.50-7.58 (m, 2H), 8.00-8.05 (m, 1H).

### Step 2—Synthesis of (4-Bromo-2,6-dimethylphenyl)hydrazine (4)

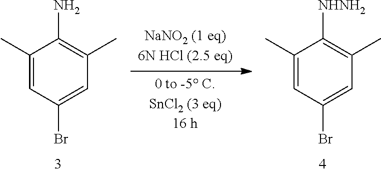

| S. | | Quantity | Vol. | | | |
|---|---|---|---|---|---|---|
| No | Reagent | (g) | (mL) | MW | Moles | Eq. |
| 1 | 4-bromo-2,6- | 100 | | 200.08 | 0.499 | 1 |
| | dimethylaniline | | | | | |
| 2 | 6N HCl | | 210 | | 1.249 | 2.5 |
| 3 | Sodium nitrite | 34.5 | | 69 | 0.499 | 1 |
| 4 | Tin (II) chloride | 340 g | | 225.65 | 1.497 | 3 |
| | dihydrate | | | | | |

### Apparatus Set-Up:

A 3 L 3-necked round-bottomed flask, equipped with a mechanical overhead stirrer, condenser, nitrogen inlet and exhaust.

### Experimental Procedure:

1) To the 6N solution of HCl in water, 4-bromo-2,6-dimethylaniline (3) (100 g, 0.499 mol) was added at −5° C. and stirred for 30 minutes.
2) Solution of sodium nitrite (34.5 g, 0.499 mol) in water (175 mL) was added slowly and stirred for 45 minutes. Then the solution of tin (II) chloride in 1:1 HCl:H₂O was added slowly with vigorous stirring.
3) The reaction mixture was allowed to stir at RT for 16 h. Then the mixture was filtered and washed with water and ether.
4) The solid was dissolved in a mixture of 10N NaOH (1 L) and ether (˜1 h). The organic layer was separated and the aqueous layer was extracted with ether (1 L×2).
5) The organic layer was dried over sodium sulphate and concentrated under vacuum. The residue (62 g) was crystallized with petroleum ether to yield 55 g (51%) of (4-Bromo-2,6-dimethylphenyl)hydrazine (4) as pale yellow solid.

¹H-NMR (400 MHz, CDCl₃): δ [ppm] 2.24 (s, 6H), 3.97 (brs, 2H), 7.06 (s, 2H).

### Step 3—Synthesis of 1-(4-Bromo-2,6-dimethylphenyl)-3-methyl-5-phenyl-1H-[1, 2, 4]triazole (5)

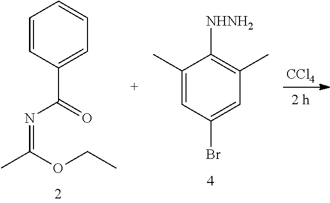

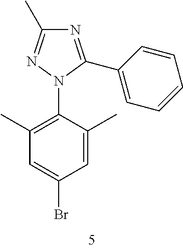 [SMILES: Cc1nc(-c2ccccc2)n(-c2c(C)cc(Br)cc2C)n1]

| S. | | Quantity | Vol. | | | |
|---|---|---|---|---|---|---|
| No | Reagent | (g) | (mL) | MW | Moles | Eq. |
| 1 | N-(1-Ethoxy-ethyl- | 46 | | 191.23 | 0.24 | 1 |
| | idene)-benzamide | | | | | |
| 2 | (4-Bromo-2,6- | 52 | | 215.09 | 0.24 | 1 |
| | dimethyl- | | | | | |
| | phenyl)-hydrazine | | | | | |
| 3 | CCl₄ | | 700 | | | |

### Apparatus Set-Up:

A 1 L 3-necked round-bottomed flask, equipped with a magnetic stirrer, nitrogen inlet and exhaust.

### Experimental Procedure:

1) To the solution of N-(1-Ethoxy-ethylidene)-benzamide (2) (46 g, 0.24 mol) in CCl₄ (700 mL), (4-bromo-2,6-dimethyl)phenyl hydrazine (4) (52 g, 0.24 mol) was added.
2) The solution was stirred for 2 h. Then the reaction mixture was concentrated and the crude (61 g) was purified by column chromatography over silica gel (60-120 mesh) using petroleum ether: ethyl acetate (8:2) as eluent to yield 48 g (58.3%) of 1-(4-Bromo-2,6-dimethyl-phenyl)-3-methyl-5-phenyl-1H-[1, 2, 4] triazole (5) as pale yellow oil.

¹H-NMR (400 MHz, CDCl₃): δ [ppm] 1.96 (s, 6H), 2.52 (s, 3H), 7.29-7.31 (m, 2H), 7.33 (s, 2H), 7.36-7.40 (m, 1H), 7.45-7.47 (m, 2H)

¹³C-NMR (100 MHz, CDCl₃): δ [ppm] 13.92, 17.42, 123.44, 127.13, 127.29, 128.73, 130.08, 131.53, 136.06, 137.95, 154.63, 161.33.

### Step 4—Synthesis of 1-(4-Hexyl-2,6-dimethyl-phenyl)-3-methyl-5-phenyl-1H-[1,2,4] triazole

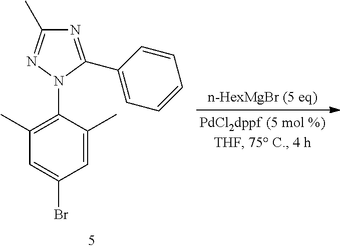 [SMILES: Cc1nc(-c2ccccc2)n(-c2c(C)cc(Br)cc2C)n1]

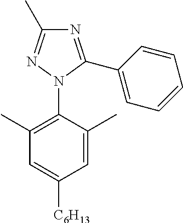

| S. | | Quantity | Vol. | | | |
|---|---|---|---|---|---|---|
| No | Reagent | (g) | (mL) | MW | Moles | Eq. |
| 1 | 1-(4-Bromo-2,6- | 48 | | 342.23 | 0.14 | 1 |
| | dimethyl-phenyl)-3- | | | | | |
| | methyl-5-phenyl- | | | | | |
| | 1H-[1,2,4] triazole | | | | | |
| 2 | n-bromohexane | | 98.5 | 165.08 | 0.701 | 5 |
| 3 | Magnesium | 20.45 | | 24.31 | 0.841 | 6 |
| 4 | PdCl₂(dppf) | 5.73 | | 816.64 | 0.007 | 0.05 |
| 5 | THF | | 1200 | | | |

### Apparatus Set-Up:

A 2 L 3-necked round-bottomed flask, equipped with a magnetic stirrer, nitrogen inlet, condensor and exhaust (2 set-up).

### Experimental Procedure:

1) Magnesium (20.45 g, 0.841 mol) was taken in anhydrous THF (500 mL) and 1, 2-dibromoethane (0.2 mL) was added. The mixture was heated to 60° C. and n-bromo hexane (98.5 mL, 0.701 mol) was added slowly to the mixture.
2) The resulting black colour solution was refluxed for 2 h. In another 2 L, 3-necked round-bottomed flask, 1-(4-Bromo-2,6-dimethyl-phenyl)-3-methyl-5-phenyl-1H-[1, 2, 4] triazole (48 g, 0.14 mol), PdCl₂(dppf) (5.73 g, 0.007 mol) and THF (700 mL) were taken.
3) The Grignard solution thus prepared was added slowly to the above mixture at 60° C. and heated for 4 h.
4) The reaction mixture was quenched with ice cooled 1.5N HCl solution (1 L) and extracted with ethyl acetate (500 mL×2). The organic layer was separated, dried over sodium sulphate and concentrated under vacuum.
5) The crude (44 g) was repeatedly purified by flash column chromatography over silica gel (230-400 mesh) using 9:1 petroleum ether and ethyl acetate as eluent to yield the following fractions yellow oil.
   3 fractions isolated.
   Fraction 1—5.5 g 99.68% purity.
   Fraction 2—10.5 g 99.51% purity. Re-purified by Combiflash chromatography.
   Fraction 2a—4.3 g with 99.57% HPLC purity (50% ACN 50% water method) and
   Fraction 2b—4.8 g with 99.1% HPLC purity (50% ACN 50% water method) are isolated.
   Fraction 3—15 g 99% purity. It was re-purified. Two fractions isolated.
   Fraction 3a—6 g. 99.12% HPLC pure by 50% ACN 50% water method.
   Fraction 3b—8.5 g. 99.29% HPLC pure by 50% ACN 50% water method. Purified by Combiflash chromatography again.
   7.8 g with 99.42% HPLC pure by 50% ACN 50% water method.
   Fraction 2b and 3a were mixed together, purified twice by Combiflash chromatography.
   7.5 g with 99.38% HPLC pure by 50% ACN 50% water method.

¹H-NMR (400 MHz, CDCl₃): δ [ppm] 0.90 (t, J=6.28 Hz, 3H), 1.27-1.35 (m, 6H), 1.60-1.63 (m, 2H), 1.95 (s, 6H), 2.53 (s, 3H), 2.60 (t, J=7.52 Hz, 2H), 6.96 (s, 2H), 7.26-7.30 (m, 2H), 7.33-7.35 (m, 1H), 7.48-7.50 (m, 2H).

¹³C-NMR (100 MHz, CDCl₃): δ [ppm] 14.04, 14.10, 17.58, 22.60, 28.83, 31.21, 31.70, 35.60, 127.24, 127.78, 128.60, 128.75, 129.81, 134.58, 135.37, 144.67, 160.91.

Comparative Metal Complex 2 was prepared according to the following reaction scheme:

### Stage 1:

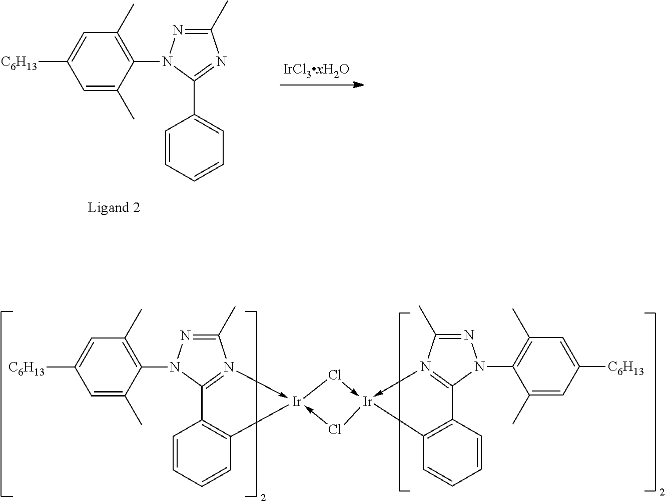

Iridium chloride hydrate (23.1 g) and Ligand 2 (50 g) were suspended in a mixture of 2-ethoxyethanol (500 mL) and water (170 mL). The mixture was purged with nitrogen for 1 h before being stirred for 14 hours with the heating bath set to 125° C. After cooling, water was added and the precipitate was isolated by suction filtration and washed on the filter with more water and methanol. The yellow-green solid was dried overnight in a vacuum oven and used without further purification.

### Stage 2:

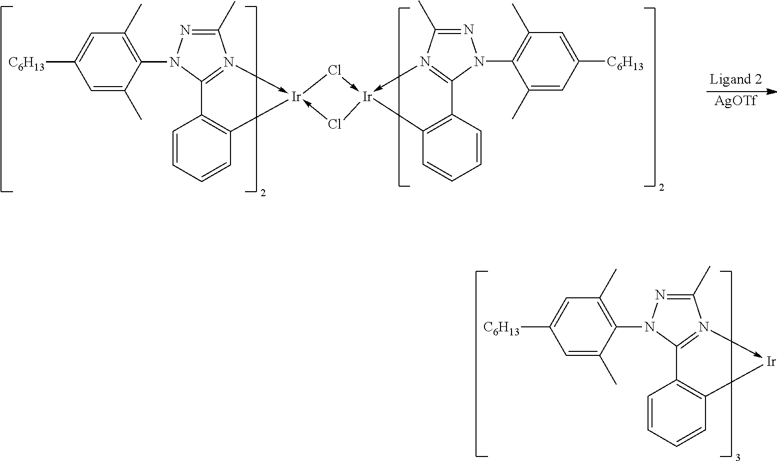

Stage 1 material (25 g) and Ligand 2 (11.8 g) were suspended in diglyme. The mixture as purged with nitrogen for 1 h before silver trifluoromethanesulfonate (7.2 g) was added in one portion and the solution was stirred for 22 h with protection from light and the heating bath set to 150° C. T.L.C. analysis showed the reaction was complete and the reaction was allowed to cool and filtered to remove the precipitated silver salts. The solvent was removed by distillation to leave the crude product which was purified by column chromatography eluting with a gradient of ethyl acetate in hexanes followed by precipitation from DCM/methanol in a yield of 44% (14.6 g). Further purification could be achieved by the use of preparative HPLC using an isocratic mixture of THF and acetonitrile.

1H NMR (referenced to CDCl₃): 7.03 (6H, d), 6.64-6.66 (3H, m), 6.56 (6H, t), 6.43 (3H, d), 2.64 (6H, t), 2.15 (9H, s), 2.09 (9H, s), 1.80 (9H, s), 1.62-1.67 (6H, m), 1.32-1.36 (18H, m), 0.90 (9H, t)

### Comparative Metal Complex 3

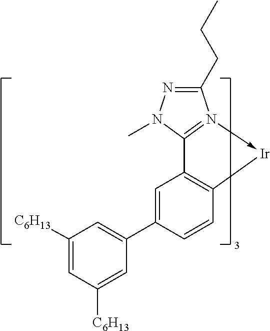

Comparative Metal Complex 3, illustrated above, was prepared according to the following reaction scheme:

### Stage 1

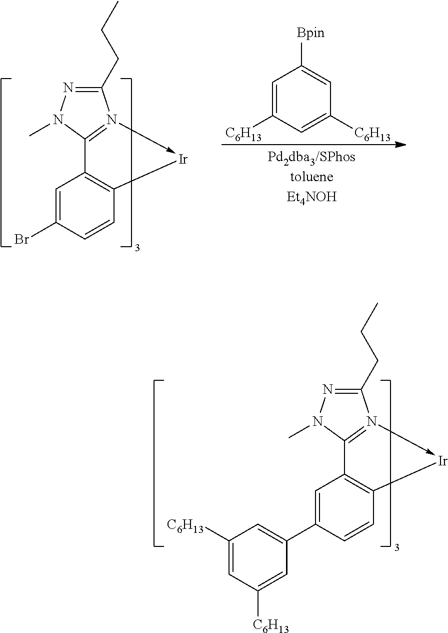

A solution of Comparative Metal Complex 1 stage 1 (4.00 g, 3.88 mmol) and 3,5-dihexylphenylboronic acid pinacol ester (5.79 g, 15.54 mmol) in toluene (90 mL) was degassed for 1 h. A further portion of degassed toluene (10 mL) was then used to transfer Pd2 dba3 (36 mg, 0.04 mmol) and SPhos (32 mg, 0.08 mmol) to the reaction flask. A degassed solution of 20 wt % tetraethylammonium hydroxide in water was added in one portion and the stirred mixture was heated to 105° C. for 24 h. After cooling the mixture was filtered into a separating funnel to remove the precipitated Pd species. The layers were separated and the aqueous layer was extracted with toluene (2×25 mL). The combined organic extracts were washed with water, dried with magnesium sulphate, filtered and concentrated to give an orange oil). The oil was purified by column chromatography eluting with a gradient of 0-30% ethyl acetate in DCM. The product was precipitated from DCM/MeOH twice to yield 4.78 g of Comparative Metal Complex 3 as a yellow powder in 81% yield. HPLC analysis showed >99.5% purity.

1H NMR (referenced to CDCl₃): 7.71 (3H, s), 7.20 (6H, s), 7.06 (3H, d), 6.93 (3H, s), 6.77 (3H, br), 4.23 (9H, s), 2.62 (12H, t), 2.21-2.26 (3H, m), 1.90-1.95 (3H, m), 1.61-1.66 (12H, m), 1.29-1.42 (36H, m), 1.17-1.23 (3H, m), 1.88 (18H, t), 0.71 (9H, t).

### Comparative Metal Complex 4

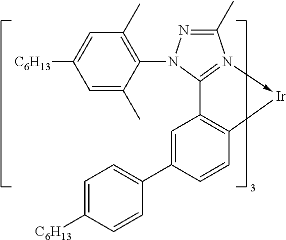

Comparative Metal Complex 4 was prepared according to the following reaction scheme:

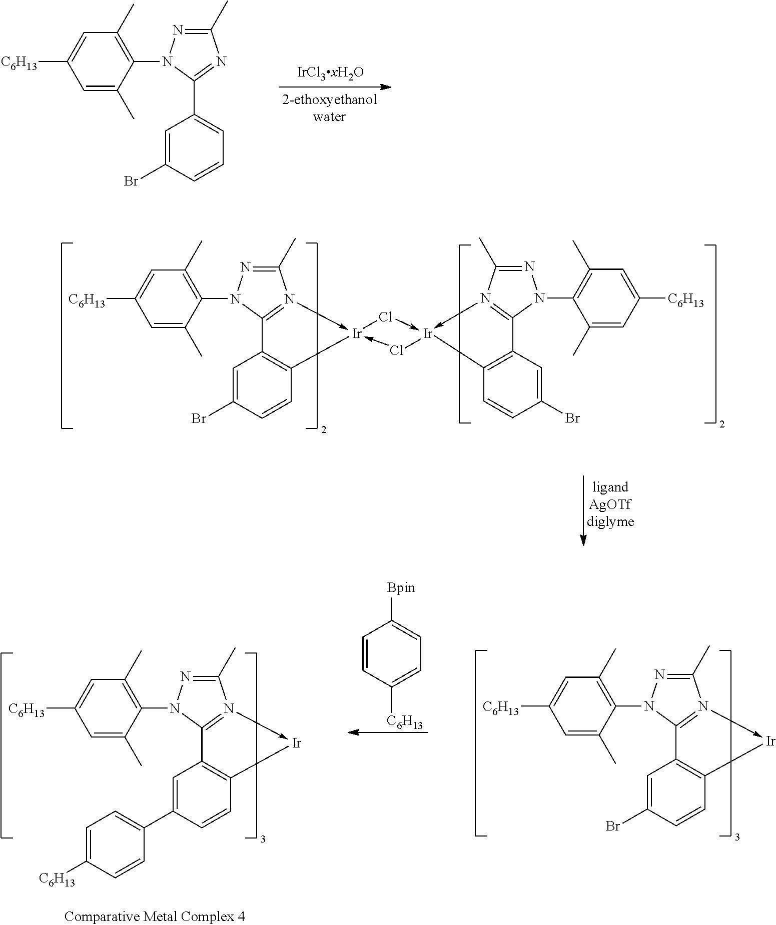

### Stage 1

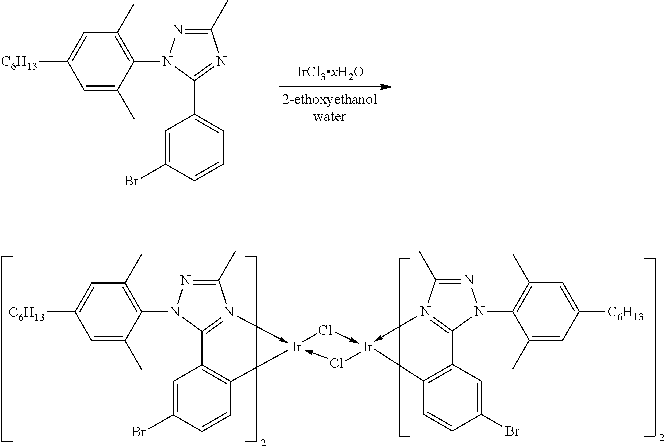

The ligand (20 g, 46.9 mmol) and iridium chloride hydrate (7.51 g, 21.3 mmol) was suspended in 2-ethoxyethanol (450 mL) and water (150 mL). The mixture was degassed for 1 h and then stirred with heating to 140° C. for 24 h. After cooling 300 mL of water was added and the resulting precipitate was filtered and washed with water and then methanol to give 19 g of stage 1 as a yellow power in 83% yield. This material was used without further purification.

### Stage 2

The stage 1 material (10.8 g, 5.00 mmol) and the ligand (10.7 g, 25.0 mmol) was suspended in 1,3-propanediol (50 mL). The mixture was degassed for 15 min and then silver triflate (2.57 g, 10 mmol) was added to the mixture. After degassed for 30 min, the suspension was stirred with heating at 160° C. by microwave irradiation. After cooling 150 mL of THF was added and the resulting precipitate was filtered and washed with THF. The filtrate was condensed and dried to give crude stage 2 as yellow powder. The crude product was purified by column chromatography eluting with toluene:ethyl acetate mixture 95:5 (vol/vol). The product was redissolved in toluene and ethyl acetate and then acetonitrile was poured into the solution to precipitate the product. This was collected by filtration to give 8.4 g of stage 2 as a yellow powder in a yield of 57%. ¹H NMR (referenced to CD2Cl2): 7.25 (s, 3H), 7.17 (s, 3H), 6.89 (d, 3H), 6.38 (d, 3H), 6.16 (d, 3H), 2.75 (t, 6H), 2.64 (s, 9H), 2.30 (s, 9H), 1.95 (s, 9H), 1.77-1.70 (m, 6H), 1.46-1.41 (m, 18H), 0.95 (t, 9H).

### Stage 3

To prepare Comparative Metal Complex 4 the stage 2 material (7.50 g, 5.11 mmol) and 4-hexylphenylboronic acid pinacol ester (5.89 g, 20.4 mmol) were dissolved in a mixture of toluene (77 mL), THF (77 mL), tert-Butyl alcohol (51 mL) and water (26 mL) and degassed for 20 min. A 20% wt degassed aqueous solution of tetraethylammonium hydroxide (33.8 g, 46.0 mmol) and PdCl2(o-tol3P)2 (120 mg, 0.15 mmol) were added into the mixture and further degassed for 30 min. The reaction mixture was the stirred with refluxing for 6 hours on an oil bath. After cooling, excess toluene was added the layers were separated and the aqueous layer extracted with toluene. The combined organic layers were condensed to give the crude product as yellow powder and redissolved in dichloromethane. Addition of heptanes followed by evaporation of dichloromethane precipitated out the product. Further purification was carried out by column chromatography eluting with toluene:ethyl acetate 90:10 (v/v). The product was redissolved in toluene and ethyl acetate and then acetonitrile was poured into the solution to precipitate the product. This was collected by filtration to give 2.6 g of complex 5 as a bright yellow powder in a yield of 30%. 1H NMR (referenced to CD2Cl2): 7.21 (d, 6H), 7.17-7.10 (m, 12H), 7.05 (d, 3H), 6.77 (d, 3H), 6.99 (d, 3H), 2.75 (t, 6H), 2.62 (t, 6H), 2.23 (d, 18H), 1.91 (s, 9H), 1.83-1.73 (m, 6H), 1.70-1.59 (m, 6H), 1.53-1.32 (m, 36H), 1.03-0.98 (m, 18H).

### Metal Complex Example 1

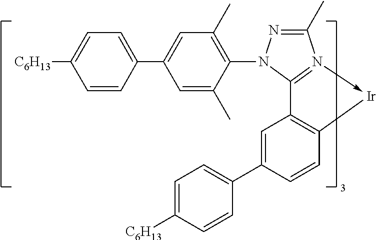

Metal Complex Example 1 was prepared according to the following reaction scheme:

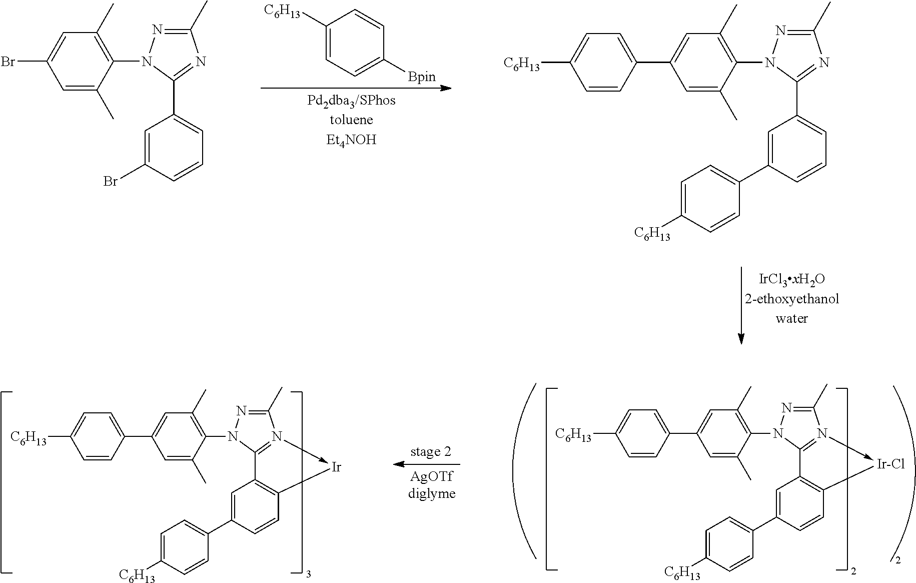

### Stage 1

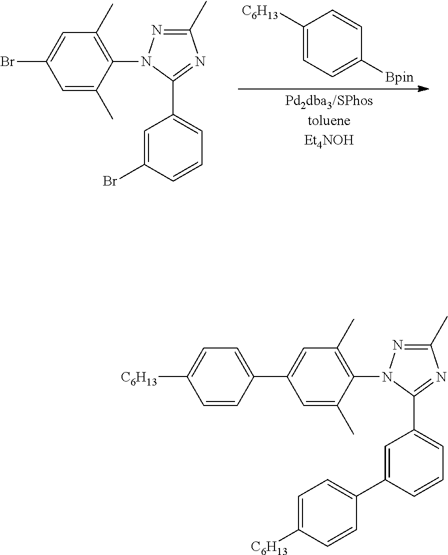

The dibromide (41 g, 97.4 mmol) and 4-hexylphenylboronic acid pinacol ester (70.16 g, 243.4 mmol) were dissolved in toluene (1.4 L) and desgassed for 1 h. An 20% wt aqueous solution of tetraethylammonium hydroxide and a further 30 mL toluene were separately degassed for 0.5 h. The base was added to the reaction mixture in one portion and the 30 mL toluene was used to transfer Pd₂ dba₃ (890 mg, 0.97 mmol) and SPhos (800 mg, 1.95 mmol) into the reaction mixture which was stirred with heating at 105° C. for 20 h. After cooling, the layers were separated and the aqueous layer extracted with toluene (200 mL). The combined organic layers were dried with magnesium sulphate, filtered and concentrated to yield a black oil which was filtered through a plug of silica (diameter 15 cm, height 8 cm) and eluted with hexanes:ethyl acetate 3:1 (v/v) and then hexanes:ethyl acetate 1:1 (v/v) to obtain 62.77 g of product as a solid after oven-drying GCMS showed ˜10% 4-hexylphenylboronic acid pinacol ester was still present. The material was used without further purification.

### Stage 2

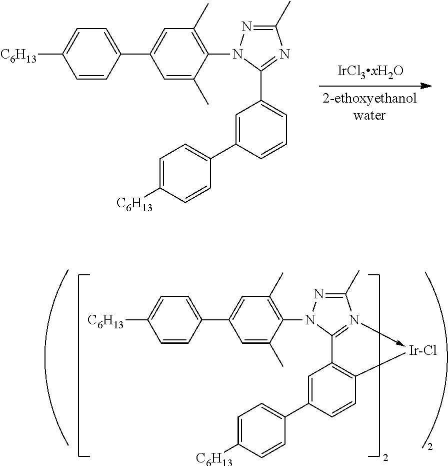

Stage 1 material (18.4 g, 28.36 mmol) and Iridium chloride hydrate (4.00 g, 11.34 mmol) were suspended in 2-ethoxyethanol (165 mL) and water (55 mL). The mixture was degassed for 1 h before being stirred with heating to 135° C. for 20 h. After cooling 175 mL water was added and the precipitate was filtered and washed with 100 mL water and dried in the oven to give 11.98 g of stage 2 material in a yield of 76%. The material was used without further purification.

### Stage 3

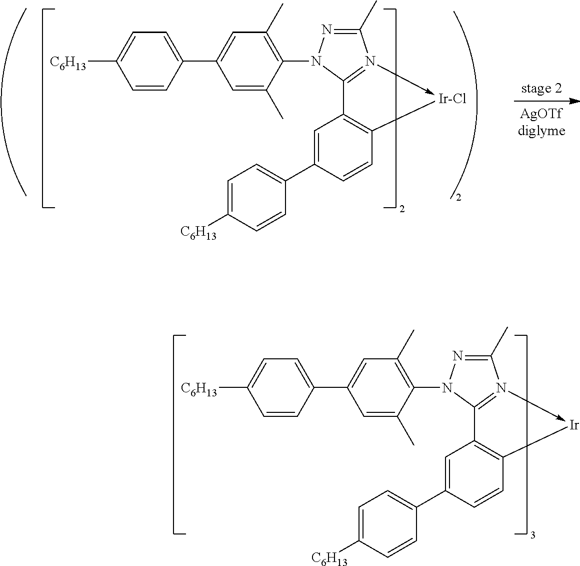

To prepare Metal Complex Example 1, the stage 2 material (11.98 g, 4.30 mmol), stage 1 material (36.67 g, 68.06 mmol) and silver triflate (5.83 g, 22.69 mmol) were dissolved in diglyme (120 mL). The moisture was degassed for 1 h before being stirred at 170° C. for 20 h. After cooling the solvent was removed by distillation and the residue was dissolved in the minimum of DCM. Addition of acetonitrile precipitated out the crude product as a yellow powder. This precipitation was repeated twice. The product was further purified by column chromatography eluting with hexanes:ethyl acetate 3:1 (v/v). The product was subjected to a final DCM/acetonitrile precipitation to give 11.89 g of product as a yellow powder in a yield of 72%. HPLC analysis showed >98.5% purity. 1H NMR (referenced to CDCl₃): 7.56 (6H, d), 7.51 (3H, s), 7.44 (3H, s), 7.32 (6H, d), 7.09 (6H, d), 7.02 (3H, dd), 6.98 (6H, d), 7.76 (3H, s), 6.69 (3H, d), 2.70 (6H, t), 2.50 (6H, t), 2.29 (9H, s), 2.21 (9H, s), 1.94 (9H, s), 1.66-1.71 (6H, m), 1.56 (6H, m), 1.28-1.41 (36H, m), 0.87-0.92 (18H, dt).

### Photoluminescence Quantum Yield (PLQY)

For PLQY measurements films were spun from a suitable solvent (for example alkylbenzene, halobenzene, alkoxybenzene) on quartz disks to achieve transmittance values of 0.3-0.4. A particularly preferred solvent is ortho-xylene. Measurements were performed under nitrogen in an integrating sphere connected to Hamamatsu C9920-02 with Mercury lamp E7536 and a monochromator for choice of exact wavelength.

TABLE 1
5 wt % emitter in HOST1

| | Excitation | | | | |
|---|---|---|---|---|---|
| | wavelength/ | | | | |
| Emitter | nm | PLQY/% | λₘₐₓ/nm | CIE X | CIE Y |
| Comparative | 300 | 78 | 474 | 0.158 | 0.301 |
| Metal Complex 1 | | | | | |
| Comparative | 300 | 81 | 457 | 0.155 | 0.213 |
| Metal Complex 2 | | | | | |
| Comparative | 300 | 84 | 468 | 0.158 | 0.295 |
| Metal Complex 3 | | | | | |
| Comparative | 300 | 77 | 473 | 0.156 | 0.327 |
| Metal Complex 4 | | | | | |
| Metal Complex | 300 | 79 | 474 | 0.157 | 0.341 |
| Example 1 | | | | | |

As can be seen in Table 1, at low emitter loadings Metal Complex Example 1 shows comparable PLQY and colour to the comparative examples. Table 2 shows the PLQY data for a higher emitter weight percentage. As can be seen the PLQY of Metal Complex Example 1 does not decrease even at high emitter loadings. For emitters with less bulky substituents, for example Comparative Metal Complex 4, the PLQY is reduced at higher emitter loadings.

TABLE 2
36 wt % emitter in HOST1

| | Excitation | | | | |
|---|---|---|---|---|---|
| | wavelength/ | | | | |
| Emitter | nm | PLQY/% | λₘₐₓ/nm | CIE X | CIE Y |
| Comparative | 300 | 67 | 474 | 0.158 | 0.336 |
| Metal Complex 4 | | | | | |
| Metal Complex | 300 | 73 | 475 | 0.159 | 0.354 |
| Example 1 | | | | | |

### Device Examples

### General Device Process

Organic light-emitting devices having the following structure were prepared:

### ITO/HIL/HTL/LEL/Cathode

wherein ITO is an indium-tin oxide anode; HIL is a hole-injecting layer comprising a hole-injecting material, HTL is a hole-transporting layer, and LEL is a light-emitting layer containing a metal complex and a host polymer and formed by spin-coating.

A substrate carrying ITO was cleaned using UV/Ozone. A hole injection layer was formed to a thickness of about 35 nm by spin-coating an aqueous formulation of a hole-injection material available from Plextronics, Inc. A hole transporting layer was formed to a thickness of about 22 nm by spin-coating a crosslinkable hole-transporting polymer and crosslinking the polymer by heating. A light-emitting layer was formed by depositing a light-emitting composition containing a host polymer doped with a blue light-emitting metal complex to a thickness of about 75 nm by spin-coating. A cathode was formed by evaporation of a first layer of a sodium fluoride to a thickness of about 2 nm, a second layer of aluminium to a thickness of about 100 nm and a third layer of silver to a thickness of about 100 nm.

In the case of blue OLEDs, the blue light-emitting metal complex is the only emissive material in the light-emitting layer.

In the case of white OLEDs, a blue light-emitting metal complex, a green emitting metal complex Green 1, which is a dendrimeric metal complex as described in WO 02/066552, and an red-emitting metal complex Red 1, as described in WO 2012/153082, are provided in the light-emitting layer.

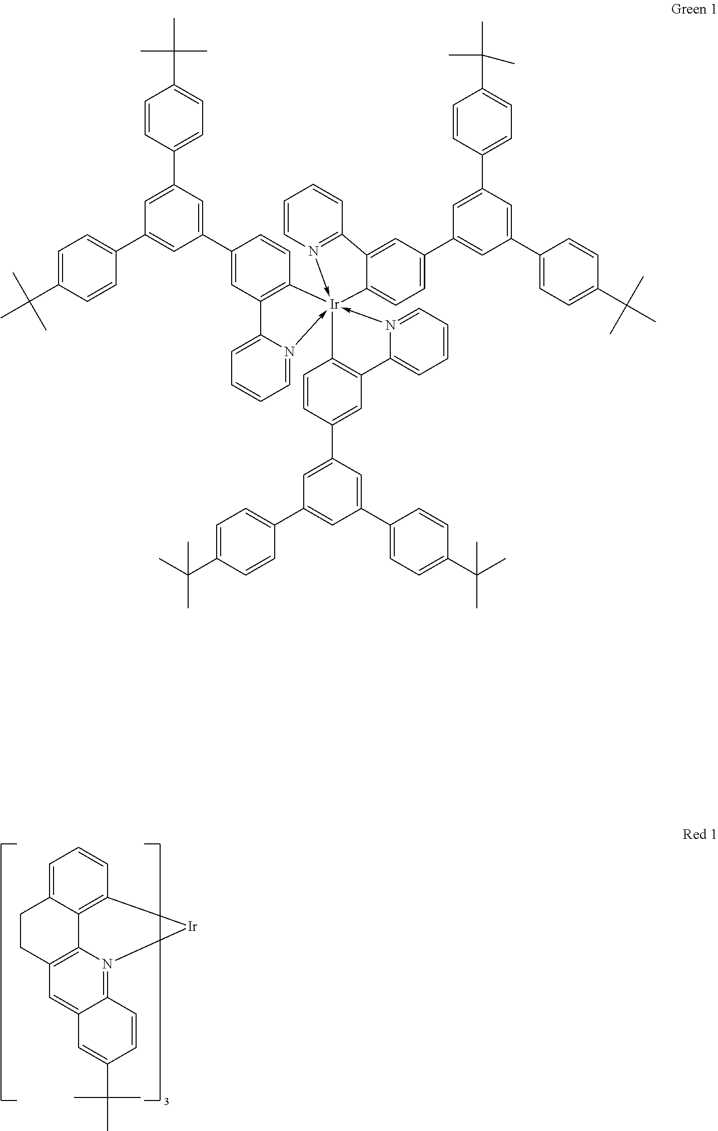

TABLE 3
Polymer compositions and molecular weight characteristics

| | Monomers (mol %) | | | | | | |
|---|---|---|---|---|---|---|---|
| Polymer | Diesters | Dibromides | Mz | Mw | Mp | Mn | Pd |
| HTP1 | 1 (50) | 3 (35) | 697,000 | 320,000 | 247,000 | 41,700 | 7.69 |
| | | 4 (10) | | | | | |
| | | 5 (5) | | | | | |
| Host 1 | 6 (50) | 7 (45), 8 (5) | 1,971,000 | 801,000 | 829,000 | 22,000 | 36.13 |
| Host 2 | 1 (35), | 8 (50) | 381,000 | 222,000 | 231,000 | 51,000 | 4.38 |
| | 19 (15) | | | | | | |
| Host 3 | 1 (50) | 10 (50) | 268,000 | 126,000 | 125,000 | 16,000 | 7.92 |
| Host 4 | 7 (50) | 8 (50), 9 | 760,000 | 400,000 | 480,000 | 21,000 | 19.38 |
| | | (50) | | | | | |

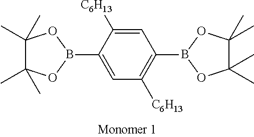

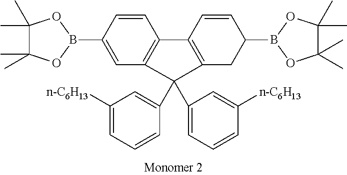

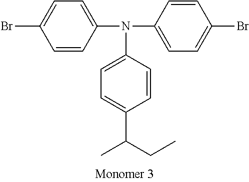 [SMILES: CCC(C)c1ccc(N(c2ccc(Br)cc2)c2ccc(Br)cc2)cc1]

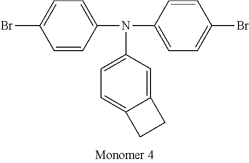 [SMILES: Brc1ccc(N(c2ccc(Br)cc2)c2ccc3c(c2)CC3)cc1]

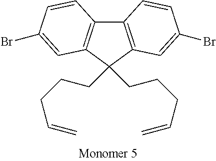 [SMILES: C=CCCCC1(CCCC=C)c2cc(Br)ccc2-c2ccc(Br)cc21]

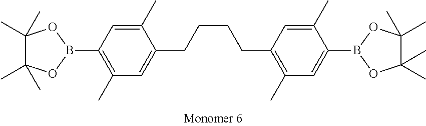

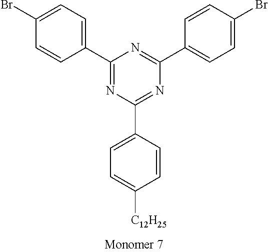

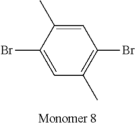

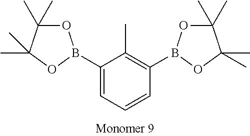

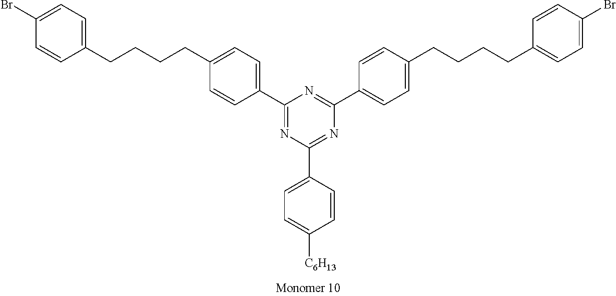

### Device Example 1

A blue OLED was formed according to the General Process in which HTL was formed by spin-coating hole-transporting polymer HTP1, and a blue light-emitting layer was formed by spin-coating a blue phosphorescent metal complex as identified in Table 4 and host polymer Host 3. HTP1 and Host 3 were each formed by Suzuki polymerisation as described in WO 00/53656 of monomers set out in Table 3.

TABLE 4

| | | Host:Metal |
|---|---|---|
| | | complex |
| Device | Light-emitting metal complex | weight ratio |
| Device Example 1 | Metal Complex Example 1 | 64:36 |
| Comparative Device 1 | Comparative Metal Complex 2 | 64:36 |

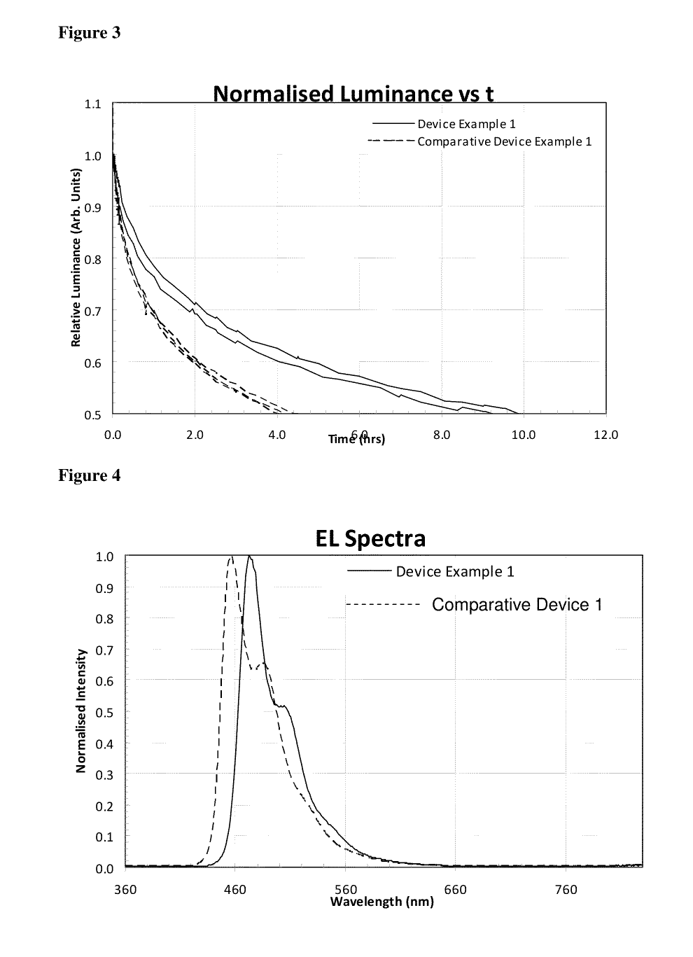

With reference to FIG. 3, the half-life of Device Example 1 is considerably longer than that of Comparative Device 1.

With reference to FIG. 4, Comparative Device 1 produces light having a peak wavelength at a slightly shorter wavelength that light produced by Device Example 1. Without wishing to be bound by any theory, it is believed that the larger number of aromatic substituents, and greater extent of conjugation, of Metal Complex Example 1 results in a longer wavelength emission peak for this material.

### Device Example 2

An exemplary blue OLED (Device Example 2) and a comparative blue OLED (Comparative Device 2) were formed according to Device Example 1 except that Host 4 was used in place of Host 3.

With reference to FIG. 5, the electroluminescent spectra for Device Example 2 and Comparative Device 2 are similar.

The time taken for Device Example 2 to fall to 70% of an initial luminance at constant current was more than 2 times longer than the corresponding time for Comparative Device 2.

The time taken for Device Example 2 to fall to 50% of an initial luminance at constant current was about 1.6 times longer than the corresponding time for Comparative Device 2.

### Device Example 3

A exemplary blue OLED was prepared according to Device Example 1, and comparative devices containing Comparative Metal Complex 3 and Comparative Metal Complex 4 were used in place of Metal Complex Example 1. Host:Metal Complex ratios are given in Table 5.

TABLE 5

| | | Host:Metal |
|---|---|---|
| | | complex |
| Device | Light-emitting metal complex | weight ratio |
| Device Example 3 | Metal Complex Example 1 | 64:36 |
| Comparative Device 3A | Comparative Metal Complex 4 | 64:36 |
| Comparative Device 3B | Comparative Metal Complex 3 | 64:36 |

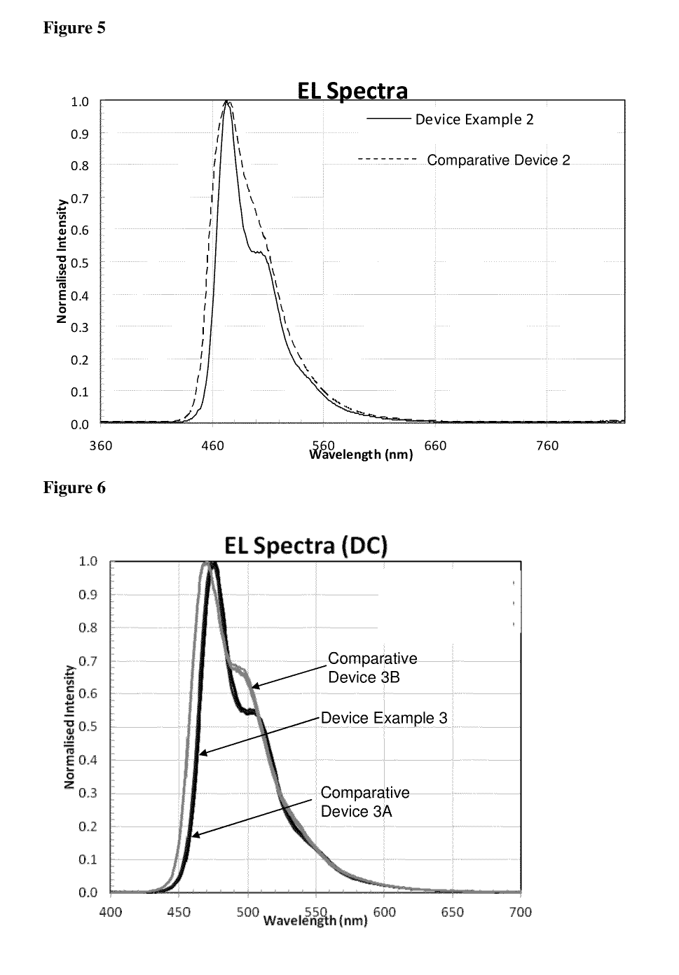

With reference to FIG. 6, the electroluminescent spectra of Device Example 3 and Comparative Devices 3A and 3B are similar (Device Example 3 and Comparative Device 3A spectra in FIG. 6 being almost identical).

The time taken for Device Example 3 to fall to 50% of an initial luminance at constant current is more than double the time taken by Comparative Device 3A and more that treble the time taken by Comparative Device 3B.

### Device Example 4

A white OLED was formed according to the General Process in which HTL was formed by spin-coating hole-transporting polymer HTP1, and a white light-emitting layer was formed by spin-coating a blue phosphorescent metal complex as identified in Table 6 with green-emitting complex Green 1, orange-emitting complex Red 1 and host polymer Host 4. HTP1 and Host 4 were each formed by Suzuki polymerisation as described in WO 00/53656 of monomers set out in Table 3. A comparative device was also prepared.

TABLE 6

| | | Host:Blue |
|---|---|---|
| | | complex:Green |
| | | complex:Orange |
| | Blue phosphorescent metal | complex |
| Device | complex | weight ratio |
| Device Example 4 | Metal Complex Example 1 | 63:35:1:1 |
| Comparative | Comparative Metal Complex 1 | 53:45:1:1 |
| Device 4 | | |

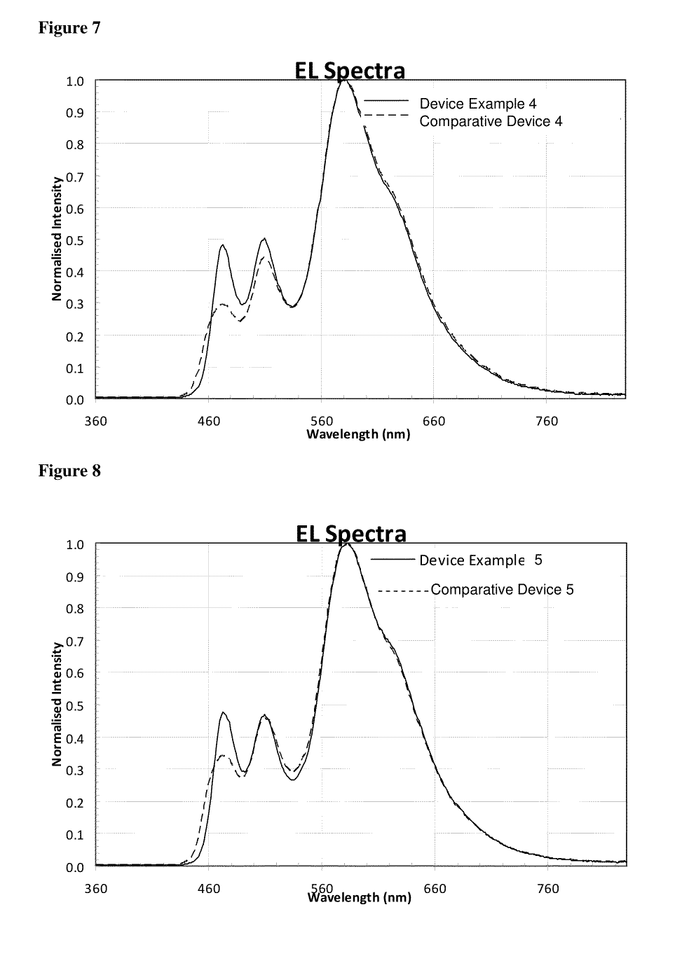

With reference to FIG. 7, the electroluminescent spectra for Device Example 4 and Comparative Device 4 are similar; both devices have a blue peak in the region of about 470 nm.

The times taken for Device Example 4 to fall to 70% and to 50% of an initial luminance at constant current were each about 2.8 times longer than the corresponding times for Comparative Device 4.

### Device Example 5

An exemplary white OLED (Device Example 5) and a comparative device (Comparative Device 5) were formed as described in Device Example 4 except that Host 3 was used in place of Host 4.

With reference to FIG. 8, the electroluminescent spectra for Device Example 5 and Comparative Device 5 are similar; both devices have a blue peak in the region of about 470 nm.

The time taken for Device Example 5 to fall to 70% of an initial luminance at constant current was about 2.6 times longer than the corresponding time for Comparative Device 5.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An unsubstituted or substituted phosphorescent compound of formula (I): 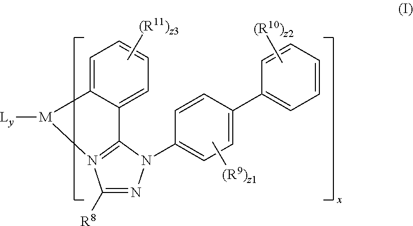
wherein:
M is a transition metal;
L in each occurrence is independently a mono- or poly-dentate ligand;
R⁸ is H or a substituent;
R⁹ and R¹⁰ are each independently selected from the group consisting of branched, linear or cyclic C₁₋₂₀ alkyl wherein non-adjacent C atoms of the C₁₋₂₀ alkyl may be replaced with —O—, —S—, —NR¹²—, —SiR¹²₂— or —COO— and one or more H atoms may be replaced with F or —NR¹²₂, wherein R¹² is H or a substituent;
R¹¹ in each occurrence is independently H or a substituent, wherein two groups R¹¹ may be linked to form a ring;
x is at least 1;
y is 0 or a positive integer; and
z1, z2 and z3 are each independently 0 or a positive integer.

2. A compound according to claim 1 wherein M is selected from iridium, platinum, osmium, palladium, rhodium and ruthenium.

3. A compound according to claim 1 or 2 wherein y is 0 and x is 3.

4. A compound according to claim 1 wherein R⁸ is selected from the group consisting of:
substituted or unsubstituted aryl or heteroaryl, optionally unsubstituted phenyl or phenyl substituted with one or more C₁₋₂₀ alkyl groups; and
branched, linear or cyclic C₁₋₂₀ alkyl wherein non-adjacent C atoms of the C₁₋₂₀ alkyl may be replaced with —O—, —S—, —NR³—, —SiR³₂— or —COO— and one or more H atoms may be replaced with F, wherein R³ is H or a substituent, optionally C₁₋₂₀ alkyl or phenyl that may be unsubstituted or substituted with one or more C₁₋₂₀ alkyl groups.

5. A compound according to claim 1 wherein z3 is at least 1.

6. A compound according to claim 5 wherein R¹¹ in each occurrence is independently selected from the group consisting of R¹⁴, OR¹⁴, SR¹⁴, NR¹⁴₂, PR¹⁴₂, P(═O)R¹⁴₂, wherein R¹⁴ in each occurrence is independently selected from the group consisting of C₁₋₄₀ hydrocarbyl.

7. A compound according to claim 1 of formula (Ia): 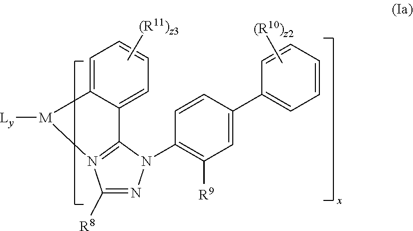
wherein R⁸, R⁹, R¹⁰, R¹¹, z2, z3, L, M, x and y are as defined in any of claims 1-7.

8. A compound according to claim 1 of formula (Ib): 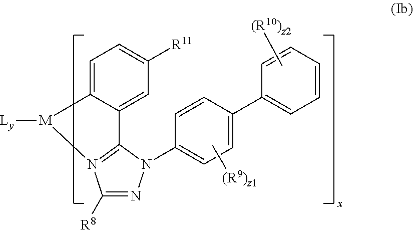
wherein R⁸, R⁹, R¹⁰, R¹¹, z1, z2, L, M, x and y are as defined in any of claims 1-7.

9. A compound according to claim 1 wherein z3 is at least 2 and two groups z3 are linked to form a monocyclic or polycyclic ring.

10. A compound according to claim 1 of formula (Ic): 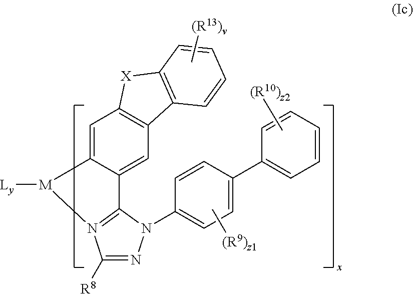
wherein R⁸, R⁹, R¹⁰, R¹³, z1, z2, L, M, x and y are as defined in any of claims 1-7, X in each occurrence is O, S, NR¹⁴, PR¹⁴, P(═O)R¹⁴, SiR¹⁴₂ or CR¹⁴₂, and v is 0 or a positive integer.

11. A compound according to claim 1 wherein the compound has a photoluminescent spectrum having a peak wavelength in the range of 400-490 nm.

12. A composition comprising a host material and a compound according to claim 1.

13. A composition according to claim 12 wherein the host material is blended with the compound.

14. A composition according to claim 13 wherein the host material is a polymer and the compound is bound in a main chain of the polymer, provided in a side-chain of the polymer or provided as an end-group of the polymer.

15. A composition according to claim 13 or 14 wherein the host is a polymer comprising a repeat unit comprising triazine.

16. A composition according to claim 13 wherein the energy gap between the HOMO of the host material and the LUMO of the compound of formula (I) is greater than 2.2 eV.

17. A solution comprising a compound or composition according to claim 1 dissolved in one or more solvents.

18. An organic light-emitting device comprising an anode, a cathode and a light-emitting layer between the anode and cathode wherein the light-emitting layer comprises a compound or composition according to claim 1.

19. A method of forming an organic light-emitting device according to claim 18 comprising the step of depositing the light-emitting layer over one of the anode and cathode, and depositing the other of the anode and cathode over the light-emitting layer.

20. A method according to claim 19 wherein the light-emitting layer is formed by depositing a solution and evaporating one or more solvents.
